(19) United States
(12) Patent Application Publication
(10) Pub. No.: US 2026/0107659 A1
(43) Pub. Date: Apr. 16, 2026

(54) DISPLAY DEVICE AND ELECTRONIC DEVICE INCLUDING THE SAME

(71) Applicant: Samsung Display Co., Ltd., Yongin-si (KR)

(72) Inventors: Sung Jae PARK, Yongin-si (KR); Jae Bum CHO, Yongin-si (KR); Na Young KIM, Yongin-si (KR); Dae Wook KIM, Yongin-si (KR); Je Won YOO, Yongin-si (KR); Choong Youl IM, Yongin-si (KR); Jong Beom HONG, Yongin-si (KR); Pil Soon HONG, Yongin-si (KR); Kyu Su AHN, Yongin-si (KR)

(21) Appl. No.: 19/266,002

(22) Filed: Jul. 10, 2025

(30) Foreign Application Priority Data
Oct. 16, 2024 (KR) 10-2024-0141657
Oct. 31, 2024 (KR) 10-2024-0152669

(51) Int. Cl. H10K 59/80

(52) U.S. Cl. CPC H10K 59/80515; H10K 59/80521; H10K 59/8731; H10K 59/8791

(57) ABSTRACT

A display device and an electronic device are provided. The display device includes, a substrate, a plurality of light-emitting elements on the substrate and each including a first electrode, a light emitting layer, and a second electrode, an encapsulation film on the plurality of light emitting elements, a color filter layer on the encapsulation film, and a first pixel and a second pixel each including the plurality of light emitting elements, wherein the first electrodes of each of the first pixel and the second pixel include a plurality of concave portions on an upper surface of each of the first electrodes and having a concave shape toward the substrate, and a pattern of the plurality of concave portions included in the first electrode of the first pixel is different from a pattern of the plurality of concave portions included in the first electrode of the second pixel.

### CROSS-REFERENCE TO RELATED APPLICATIONS

This application claims priority to and the benefits of Korean Patent Application No. 10-2024-0141657, filed on Oct. 16, 2024, in the Korean Intellectual Property Office, and Korean Patent Application No. 10-2024-0152669, filed on Oct. 31, 2024, in the Korean Intellectual Property Office the entire disclosure of each of which are incorporated herein by reference.

### BACKGROUND

### 1. Field

One or more aspects of embodiments of the present disclosure relate to a display device and an electronic device including the same.

### 2. Description of the Related Art

As an information society develops, the demand for a display device for displaying an image is increasing in various forms. For example, the display device has been applied to various electronic devices such as smartphones, digital cameras, laptop computers, navigation devices, smart televisions and/or the like. The display devices may be flat panel display devices such as liquid crystal display devices, field emission display devices, organic light emitting display devices and/or the like. Among the flat panel display devices, the light emitting display device may include a light emitting element in which each of the pixels of a display panel may emit light by itself, thereby displaying an image without a backlight unit providing the light to the display panel.

### SUMMARY

One or more aspects of embodiments of the present disclosure are directed toward a display device that minimizes an external light reflection diffraction phenomenon and an electronic device including the same.

However, it should be noted that the preceding are merely examples, and the scope of the present disclosure is not limited to the aspects set forth herein. The preceding and other aspects of the present disclosure will become more apparent to one of ordinary skill in the art to which the present disclosure pertains by referencing the following detailed description of the present disclosure.

According to one or more embodiments of the present disclosure, there is provided a display device including, a substrate, a first pixel and a second pixel each including a plurality of light emitting elements, each plurality of light-emitting elements on the substrate and each including a first electrode, a light emitting layer, and a second electrode, an encapsulation film on each plurality of light emitting elements, and a color filter layer on the encapsulation film, wherein each first electrode of the first pixel and the second pixel includes a plurality of concave portions on an upper surface of each first electrode and having a concave shape toward the substrate, and a pattern of the plurality of concave portions included in the first electrode of the first pixel is different from a pattern of the plurality of concave portions included in the first electrode of the second pixel.

In one or more embodiments, the plurality of concave portions included in the first electrode of the first pixel are irregularly on the upper surface of the first electrode of the first pixel, and the plurality of concave portions included in the first electrode of the second pixel are irregularly on the upper surface of the first electrode of the second pixel.

In one or more embodiments, in each of the first pixel and the second pixel, the upper surface of the first electrode includes a first portion and a second portion having the same area at different positions, and a number of the plurality of concave portions on the first portion is different from a number of the plurality of concave portions on the second portion.

In one or more embodiments, in each of the first pixel and the second pixel, the upper surface of the first electrode includes a first portion and a second portion having a same area at different positions, and an average size of the plurality of concave portions on the first portion is different from an average size of the plurality of concave portions on the second portion.

In one or more embodiments, the plurality of light emitting elements in the first pixel are at a same position as the plurality of light emitting elements in the second pixel.

In one or more embodiments, a portion (some) of the plurality of concave portions at least partially overlap each other.

In one or more embodiments, a portion (some) of the plurality of concave portions have different sizes.

In one or more embodiments, a maximum value of widths of the plurality of concave portions is at least twice (e.g., or more) of a minimum value.

In one or more embodiments, a width of the plurality of concave portions is 2 micrometer (μm) to 6 μm.

In one or more embodiments, a depth of the plurality of concave portions is 0.2 μm to 0.4 μm.

In one or more embodiments, the plurality of light emitting elements include a first light emitting element that may be to emit a first color, a second light emitting element that may be to emit a second color, and a third light emitting element that may be to emit a third color, and a range of widths of the plurality of concave portions included in the first electrode of the first light emitting element, a range of widths of the plurality of concave portions included in the first electrode of the second light emitting element, and a range of widths of the plurality of concave portions included in the first electrode of the third light emitting element are different from each other, e.g., in at least some extent.

In one or more embodiments, a wavelength of light of the first color is longer than a wavelength of light of the second color, the wavelength of the light of the second color is longer than a wavelength of light of the third color, a maximum value of the widths of the plurality of concave portions included in the first electrode of the first light emitting element is greater than a maximum value of the widths of the plurality of concave portions included in the first electrode of the second light emitting element, and the maximum value of the widths of the plurality of concave portions included in the first electrode of the second light emitting element is greater than a maximum value of the widths of the plurality of concave portions included in the first electrode of the third light emitting element.

In one or more embodiments, the range of widths of the plurality of concave portions included in the first electrode of the first light emitting element is 3 μm to 6 μm, the range of widths of the plurality of concave portions included in the first electrode of the second light emitting element is 2.5 μm to 5 μm, and the range of widths of the plurality of concave portions included in the first electrode of the third light emitting element is 2.2 μm to 4.4 μm.

In one or more embodiments, the encapsulation film includes a first inorganic encapsulation film, an organic encapsulation film, and a second inorganic encapsulation film, and the organic encapsulation film has a refractive index of 1.4 to 1.6.

In one or more embodiments, upper surfaces of the light emitting layer and the second electrode each include conformal concave portions (e.g., concave portions conformally formed) along a shape of the plurality of concave portions.

According to an aspect of the present disclosure, there is provided a display device including, a substrate, a first pixel and a second pixel each including first to third light emitting elements, each of the first to third light emitting elements are on the substrate and each including a first electrode, a light emitting layer, and a second electrode, and each may be to emit first to third colors different from each other, an encapsulation film on each of the first to third light emitting elements, a color filter layer on the encapsulation film, wherein an arrangement of the first to third light emitting elements in the first pixel is equal to (the same as) an arrangement of the first to third light emitting elements in the second pixel, the first electrodes of each of the first to third light emitting elements of each of the first pixel and the second pixel include a plurality of concave portions on an upper surface of the first electrodes and having a concave shape toward the substrate, and a pattern of the plurality of concave portions included in the first electrode of the first light emitting element of the first pixel is different from a pattern of the plurality of concave portions included in the first electrode of the first light emitting element of the second pixel.

In one or more embodiments, the plurality of concave portions included in the first electrode of the first light emitting element of the first pixel are irregularly on the upper surface of the first electrode of the first light emitting element of the first pixel, and the plurality of concave portions included in the first electrode of the first light emitting element of the second pixel are irregularly on the upper surface of the first electrode of the first light emitting element of the second pixel.

In one or more embodiments, some of the plurality of concave portions at least partially overlap each other.

In one or more embodiments, in each of the first light emitting element of the first pixel and the second light emitting element of the second pixel, the upper surface of the first electrode includes a first portion and a second portion having a same area at different positions, and an average size of the plurality of concave portions on the first portion is different from an average size of the plurality of concave portions on the second portion.

According to an aspect of the present disclosure, there is provided an electronic device including a display device, wherein the display device includes, a substrate, a first pixel and a second pixel each including a plurality of light emitting elements, each plurality of light-emitting elements on the substrate and each including a first electrode, a light emitting layer, and a second electrode, an encapsulation film on each plurality of light emitting elements, and a color filter layer on the encapsulation film, wherein each first electrode of the first pixel and the second pixel includes a plurality of concave portions on an upper surface of each first electrode and having a concave shape toward the substrate, and a pattern of the plurality of concave portions included in the first electrode of the first pixel is different from a pattern of the plurality of concave portions included in the first electrode of the second pixel.

According to the display device and the electronic device including the same according to one or more embodiments of the present disclosure, the external light reflection diffraction phenomenon may be minimized.

However, the effects of the embodiments are not restricted to the one set forth herein. The preceding and other effects of the embodiments will become more apparent to one of ordinary skill in the art to which the embodiments pertain by referencing the claims.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The accompanying drawings are included to provide a further understanding of the preceding and other aspects, advantages, and features of the present disclosure and are incorporated in and constitute a part of this specification. The drawings illustrate example embodiments that will become more apparent by describing in detail embodiments thereof with reference to the attached drawings. In the drawings:

FIG. 1 is a schematic perspective view of an electronic device according to one or more embodiments;

FIG. 2 is a perspective view illustrating a display device included in the electronic device according to one or more embodiments;

FIG. 3 is a cross-sectional view of the display device of FIG. 2 viewed from a side;

FIG. 4 is a plan view illustrating an arrangement of pixels and light emitting areas in a display area of the display device according to one or more embodiments;

FIG. 5 is a plan view illustrating an arrangement of a color filter layer on the pixels and the light emitting areas of the display device according to one or more embodiments;

FIG. 6 is a cross-sectional view taken along line X1-X1′ of FIG. 5;

FIG. 7 is an enlarged cross-sectional view of area A of FIG. 6;

FIG. 8 is a cross-sectional view for describing a difference in reflection angle according to a depth of a concave portion of the display device according to one or more embodiments;

FIG. 9 is a plan view illustrating a concave area and a non-concave area in the light emitting area of the display device according to one or more embodiments;

FIG. 10 is a side view illustrating an experiment measuring reflection diffraction characteristics of the display device according to one or more embodiments;

FIG. 11 is a plan view illustrating a pixel according to a comparative example of the present disclosure;

FIG. 12 is a photograph illustrating a halo pattern among the reflection diffraction characteristics of the pixel according to the comparative example of the present disclosure;

FIG. 13 is a photograph illustrating a diffraction pattern among the reflection diffraction characteristics of the pixel according to the comparative example of the present disclosure;

FIG. 14 is a plan view illustrating a pixel according to a first embodiment;

FIG. 15 is a photograph illustrating a halo pattern among the reflection diffraction characteristics of the pixel according to the first embodiment;

FIG. 16 is a photograph illustrating a diffraction pattern among the reflection diffraction characteristics of the pixel according to the first embodiment;

FIG. 17 is a plan view illustrating a pixel according to a second embodiment;

FIG. 18 is a photograph illustrating a halo pattern among the reflection diffraction characteristics of the pixel according to the second embodiment;

FIG. 19 is a photograph illustrating a diffraction pattern among the reflection diffraction characteristics of the pixel according to the second embodiment;

FIG. 20 is a plan view illustrating a pixel according to a third embodiment;

FIG. 21 is a photograph illustrating a halo pattern among the reflection diffraction characteristics of the pixel according to the third embodiment;

FIG. 22 is a photograph illustrating a diffraction pattern among the reflection diffraction characteristics of the pixel according to the third embodiment;

FIG. 23 is a plan view illustrating a pixel according to a fourth embodiment;

FIG. 24 is a photograph illustrating a halo pattern among the reflection diffraction characteristics of the pixel according to the fourth embodiment; and

FIG. 25 is a photograph illustrating a diffraction pattern among the reflection diffraction characteristics of the pixel according to the fourth embodiment.

### DETAILED DESCRIPTION

The present disclosure will now be described more fully hereinafter, examples of which are illustrated with reference to the accompanying drawings, wherein like reference numerals refer to like elements throughout the specification, and in which one or more embodiments of the present disclosure are shown. The present disclosure may, however, be embodied in different forms and should not be construed as limited to the embodiments set forth herein. It should be noted that in the following description, only portions useful for understanding an operation according to the disclosure are described, and descriptions of other portions may be excluded so that the subject matter of the disclosure is not obscured. Accordingly, the embodiments are merely described by referring to the figures to explain the embodiments in enough detail so that the present disclosure will be thorough and complete, and its scope will be fully conveyed to those skilled in the art so they may easily implement the technical spirit of the embodiments to which the present disclosure belongs.

As used herein, the term “and/or” includes any and all combinations of one or more of the associated listed items. Throughout the disclosure, the expressions “at least one of a, b or c,” “at least any of a, b, and c,” and “at least any selected from a group consisting of a, b, and c,” and/or the like indicate only a, only b, only c, both (e.g., simultaneously) a and b, both (e.g., simultaneously) a and c, both (e.g., simultaneously) b and c, all of a, b, and c, or variations thereof, (for example, abc, ab, bc, and cc).

It will be understood that although the terms “first,” “second,” and/or the like may be used herein to describe one or more suitable components, these components should not be limited by these terms. These components are only used to distinguish one component from another. Therefore, a first component may refer to a second component within a range without departing from the scope disclosed herein.

An expression used in the singular such as “a,” “an” and “the” encompasses the expression of the plural, unless it has a clearly different meaning in the context.

It will be further understood that the terms “includes”, “include,” “including,” “having,” “have,” “has,” “comprise,” “comprises,” and/or “comprising,” as used herein specify the presence of stated features or elements, but do not preclude the presence or addition of one or more other features or elements.

It will also be understood that when a component such as a layer, film, region, plate, and/or the like is referred to as being “on” or “coupled” to another component, it may be directly on the other component, or intervening components may also be present. The same reference numbers indicate the same components throughout the specification, and thus redundant description thereof will not be provided. Sizes of elements in the drawings may be exaggerated for convenience of explanation. In embodiments, because sizes and thicknesses of components in the drawings are arbitrarily illustrated for convenience of explanation, the following embodiments are not limited thereto.

The term “may” will be understood to refer to “one or more embodiments of the present disclosure,” some of which include the described element and some of which exclude that element and/or include an alternate element. Similarly, alternative language such as “or” refers to “one or more embodiments of the present disclosure,” each including a corresponding listed item.

Spatially relative terms such as “below”, “lower”, “above”, “on top”, “on the top”, “under”, “on”, and/or the like may be used for descriptive purposes, thereby describing a relationship between one element or feature and another element(s) or feature(s) as shown in the drawings. Spatially relative terms are intended to include other directions in use, in operation, and/or in manufacturing, in addition to the direction depicted in the drawings. For example, when a device shown in the drawing is turned upside down, elements depicted as being positioned “under” other elements or features are positioned in a direction “on” the other elements or features. Therefore, in one or more embodiments, the term “under” may include both (e.g., simultaneously) directions of on and under. In some embodiments, the device may face in other directions (for example, rotated 90 degrees or in other directions) and thus the spatially relative terms used herein are interpreted according thereto.

The term “interlayer” as used herein refers to a single layer and/or all of multiple layers between the first electrode and the second electrode of the light-emitting device.

Unless otherwise defined, all terms (including chemical, technical and scientific terms) used herein have a same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

When a certain embodiment may be implemented differently, a specific process order may be performed differently from the described order. For example, two consecutively described processes may be performed substantially at the same time or performed in an order opposite to the described order.

In this context, “consisting essentially of” indicates that any additional components will not materially affect the chemical, physical, optical or electrical properties of the semiconductor film.

Hereinafter, one or more embodiments of the disclosure are described in more detail with reference to the attached drawings.

Hereinafter, embodiments of the present disclosure will be described in detail with reference to the accompanying drawings.

### Electronic Device

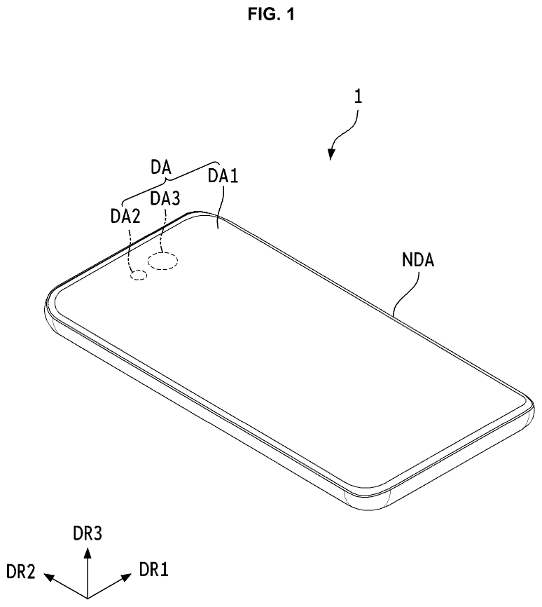

FIG. 1 is a schematic perspective view of an electronic device according to one or more embodiments.

Referring to FIG. 1, an electronic device 1 displays a moving image or a still image. The electronic device 1 may refer to any electronic device that provides a display screen. For example, the electronic device 1 may include televisions, laptop computers, monitors, billboards, Internet of things, mobile phones, smartphones, tablet personal computers (PCs), electronic watches, smartwatches, watch phones, head mounted displays, mobile communication terminals, electronic notebooks, electronic books, portable multimedia players (PMPs), navigation, game consoles, digital cameras, camcorders, and/or the like that provide the display screen.

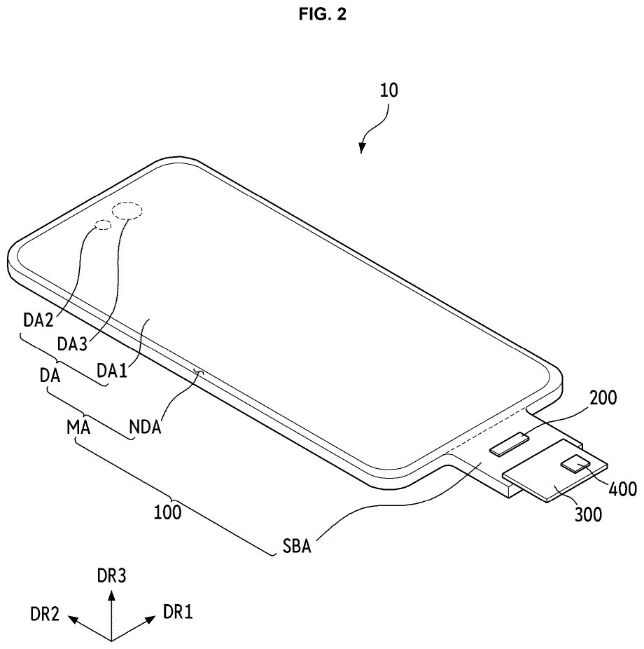

The electronic device 1 may include a display device 10 (see FIG. 2) that provides a display screen. Examples of the display device may include an inorganic light emitting diode display device, an organic light emitting display device, a quantum dot light emitting display device, a plasma display device, and a field emission display device. Hereinafter, it is illustrated that an organic light emitting diode display device is used as an example of the display device, but the present disclosure is not limited thereto and may also be applied to other display devices as long as the same technical idea is applicable thereto.

A shape of the electronic device 1 may be suitably changed. For example, the electronic device 1 may have a shape such as a rectangle with a long width, a rectangle with a long length, a square, a quadrangle with rounded corners (vertices), other polygons, or a circle. A shape of a display area DA of the electronic device 1 may also be similar to an overall shape of the electronic device 1. In FIG. 1, the electronic device 1 having a rectangular shape with a long length in a second direction DR2 is illustrated.

In the illustrated drawings, the first direction DR1 and the second direction DR2 are horizontal directions and intersect each other. For example, the first direction DR1 and the second direction DR2 may be orthogonal (perpendicular) to each other. In addition, a third direction DR3 may be a vertical direction intersecting the first direction DR1 and the second direction DR2, for example, orthogonal to the first direction DR1 and the second direction DR2. Unless otherwise defined, in the present specification, directions indicated by arrows in the first to third directions DR1, DR2, and DR3 may be referred to as one side, and the opposite directions thereof may be referred to as the other side. In addition, in the present specification, “on”, “upper side”, “upper portion”, “top”, and “upper surface” refer to a direction in which an arrow in the drawing is directed in a third direction DR3 based on the drawing, and “below”, “lower side”, “lower portion”, “bottom”, and “lower surface” refer to a direction opposite to the direction in which the arrow in the third direction DR3 is directed based on the drawing.

The electronic device 1 may include a display area DA and a non-display area NDA. The display area DA is an area in which a screen may be displayed, and the non-display area NDA is an area in which a screen is not displayed. The display area DA may also be referred to as an active area, and the non-display area NDA may also be referred to as a non-active area. The display area DA may generally occupy the center of the electronic device 1.

The display area DA may include a first display area DA1, a second display area DA2, and a third display area DA3. The second display area DA2 and the third display area DA3, which are areas in which components for adding one or more suitable functions to the electronic device 1 are disposed, may correspond to component areas.

FIG. 2 is a perspective view illustrating a display device included in the electronic device according to one or more embodiments.

Referring to FIG. 2, the electronic device 1 according to one or more embodiments may include a display device 10. The display device 10 may provide a screen displayed by the electronic device 1. The display device 10 may have a planar shape similar to that of the electronic device 1. For example, the display device 10 may have a shape similar to a rectangle having short sides in a first direction DR1 and long sides in a second direction DR2. A corner where the short side in the first direction DR1 and the long side in the second direction DR2 meet may be rounded to have a curvature, but is not limited thereto and may also be formed at a right angle. The planar shape of the display device 10 is not limited to the quadrangle, and may be formed similarly to other polygons, circles, or ovals.

The display device 10 may include a display panel 100, a display driver 200, a circuit board 300, and a touch driver 400.

The display panel 100 may include a main area MA and a sub-area SBA.

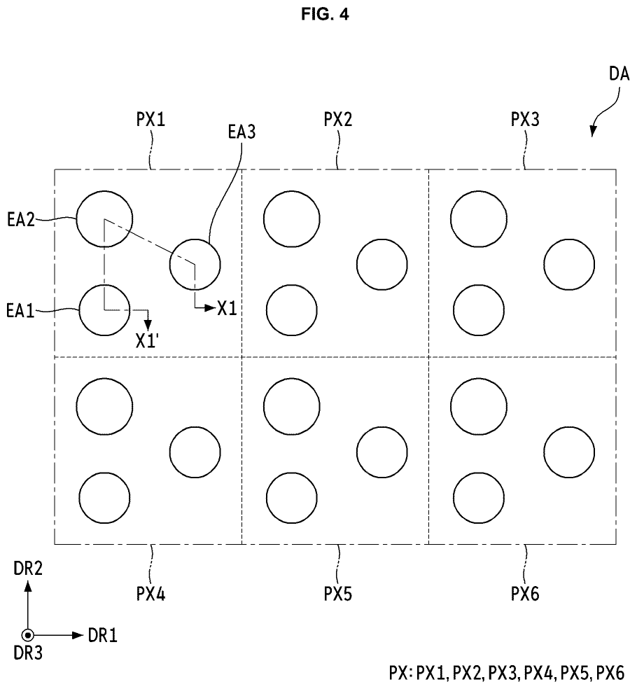

The main area MA may include a display area DA including pixels PX (see FIG. 4) displaying an image, and a non-display area NDA around the display area DA. The display area DA may be in the center of the main area MA, and the non-display area NDA may surround the display area DA. The display area DA may include a first display area DA1, a second display area DA2, and a third display area DA3. The display area DA may emit light from a plurality of light emitting areas or a plurality of opening areas. For example, the display panel 100 may include a pixel circuit including switching elements, a pixel defining film defining the light emitting areas or the opening areas, and a self-light emitting element.

For example, the self-light emitting element may include, but is not limited to, at least one of (e.g., selected from among) an organic light emitting diode (LED) including an organic light emitting layer, a quantum dot LED including a quantum dot light emitting layer, an inorganic LED including an inorganic semiconductor, and a micro LED.

The non-display area NDA may be an area outside the display area DA. The non-display area NDA may be defined as an edge area of the main area MA of the display panel 100. In one or more embodiments, the non-display area NDA may include a gate driver supplying gate signals to gate lines, and fan-out lines connecting the display driver 200 and the display area DA.

The sub-area SBA may be an area extending from one side of the main area MA. The sub-area SBA may include a flexible material that may be bent, folded, rolled, or the like. For example, when the sub-area SBA is bent, the sub-area SBA may overlap the main area MA in a thickness direction (a third direction DR3). The sub-area SBA may include the display driver 200 and a pad portion coupled (e.g., connected) to the circuit board 300. In another embodiment, the sub-area SBA may not be provided, and the display driver 200 and the pad portion may be in the non-display area NDA.

The display driver 200 may output signals and voltages for driving the display panel 100. The display driver 200 may supply data voltages to data lines. The display driver 200 may supply a power voltage to a power line and may supply a gate control signal to a gate driver. The display driver 200 may be formed as an integrated circuit (IC) and mounted on the display panel 100 by a chip on glass (COG) method, a chip on plastic (COP) method, or an ultrasonic bonding method. For example, the display driver 200 may be in the sub-area SBA, and may overlap the main area MA in the thickness direction by bending of the sub-area SBA. As another example, the display driver 200 may be mounted on the circuit board 300.

The circuit board 300 may be coupled (e.g., attached) onto the pad portion of the display panel 100 using an anisotropic conductive film (ACF). Lead lines of the circuit board 300 may be electrically coupled (e.g., connected) to the pad portion of the display panel 100. The circuit board 300 may be a flexible film such as a flexible printed circuit board, a printed circuit board, or a chip on film.

The touch driver 400 may be mounted on the circuit board 300. The touch driver 400 may be coupled (e.g., connected) to a touch sensing unit of the display panel 100. The touch driver 400 may supply a touch driving signal to a plurality of touch electrodes of the touch sensing unit, and may sense an amount of change in capacitance between the plurality of touch electrodes. For example, the touch driving signal may be a pulse signal having a predetermined frequency. The touch driver 400 may calculate whether an input is made and input coordinates based on the amount of change in capacitance between the plurality of touch electrodes. The touch driver 400 may be formed as an integrated circuit (IC).

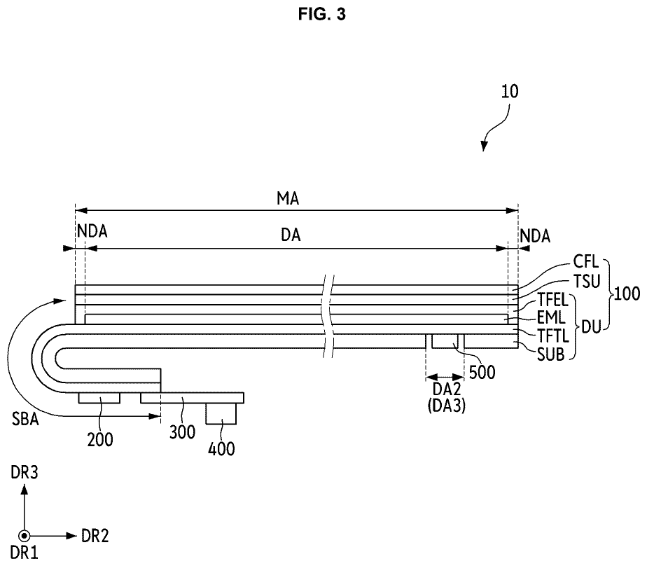

FIG. 3 is a cross-sectional view of the display device of FIG. 2 viewed from a side. FIG. 3 illustrates a state in which the sub-area SBA of the display panel 100 in the display device 10 of FIG. 2 is bent.

Referring to FIG. 3, the display panel 100 may include a display layer DU, a touch sensing layer TSU, and a color filter layer CFL. The display layer DU may include a substrate SUB, a thin film transistor layer TFTL, a light emitting element layer EML, and an encapsulation layer TFEL.

The substrate SUB may be a base substrate or a base member. The substrate SUB may be a flexible substrate that may be bent, folded, rolled, or the like. For example, the substrate SUB may include a polymer resin such as polyimide PI, but is not limited thereto. In another embodiment, the substrate SUB may include a glass material or a metal material.

The thin film transistor layer TFTL may be on the substrate SUB. The thin film transistor layer TFTL may include a plurality of thin film transistors constituting a pixel circuit of pixels. The thin film transistor layer TFTL may further include gate lines, data lines, power lines, gate control lines, fan-out lines connecting the display driver 200 and the data lines, and lead lines connecting the display driver 200 and the pad portion. Each of the thin film transistors may include a semiconductor area, a source electrode, a drain electrode, and a gate electrode. For example, when the gate driver is formed on one side of the non-display area NDA of the display panel 100, the gate driver may include the thin film transistors.

The thin film transistor layer TFTL may be in the display area DA, the non-display area NDA, and the sub-area SBA. The thin film transistors, the gate lines, the data lines, and the power lines of each of the pixels of the thin film transistor layer TFTL may be in the display area DA. The gate control lines and the fan-out lines of the thin film transistor layer TFTL may be in the non-display area NDA. The lead lines of the thin film transistor layer TFTL may be in the sub-area SBA.

The light emitting element layer EML may be on the thin film transistor layer TFTL. The light emitting element layer EML may include a plurality of light emitting elements including a first electrode, a second electrode, and a light emitting layer to emit light, and a pixel defining film defining pixels. The plurality of light emitting elements of the light emitting element layer EML may be in the display area DA.

In one or more embodiments, the light emitting layer may be an organic light emitting layer including an organic material. The light emitting layer may include a hole transporting layer, an organic light emitting layer, and an electron transporting layer. When the first electrode receives a voltage through the thin film transistor of the thin film transistor layer TFTL and the second electrode receives a cathode voltage, holes and electrons may move to the organic light emitting layer through the hole transporting layer and the electron transporting layer, respectively, and may be bonded to each other in the organic light emitting layer to emit light.

In another embodiment, the light emitting element may include a quantum dot light emitting diode including a quantum dot light emitting layer, an inorganic light emitting diode including an inorganic semiconductor, or a micro light emitting diode.

The encapsulation layer TFEL may cover an upper surface and side surfaces of the light emitting element layer EML, and may protect the light emitting element layer EML. The encapsulation layer TFEL may include at least one inorganic film and at least one organic film for encapsulating the light emitting element layer EML.

The touch sensing layer TSU may be on the encapsulation layer TFEL. The touch sensing layer TSU may include a plurality of touch electrodes for detecting a user's touch in a capacitance method, and touch lines connecting the plurality of touch electrodes and the touch driver 400. For example, the touch sensing layer TSU may sense the user's touch in a mutual capacitance method or a self-capacitance method.

In another embodiment, the touch sensing layer TSU may be on a separate substrate on the display layer DU. In this case, the substrate supporting the touch sensing layer TSU may be a base member that encapsulates the display layer DU.

The plurality of touch electrodes of the touch sensing layer TSU may be in a touch sensor area overlapping the display area DA. The touch lines of the touch sensing layer TSU may be in a touch peripheral area overlapping the non-display area NDA.

The color filter layer CFL may be on the touch sensing layer TSU. The color filter layer CFL may include a plurality of color filters corresponding to each of the plurality of light emitting areas. Each of the color filters may selectively transmit light of a selected wavelength and block or absorb light of a different wavelength. The color filter layer CFL may absorb a portion of light introduced from the outside of the display device 10 to reduce reflected light caused by external light. Therefore, the color filter layer CFL may prevent color distortion caused by reflection of external light.

As the color filter layer CFL is directly on the touch sensing layer TSU, the display device 10 may not require a separate substrate for the color filter layer CFL. Therefore, the display device 10 may have a relatively small thickness.

In some embodiments, the display device 10 may further include an optical device 500. The optical device 500 may be in the second display area DA2 or the third display area DA3. The optical device 500 may emit or receive light in infrared, ultraviolet, and visible light bands. For example, the optical device 500 may be an optical sensor that detects light incident on the display device 10, such as a proximity sensor, an illuminance sensor, and a camera sensor or an image sensor.

FIG. 4 is a plan view illustrating an arrangement of pixels and light emitting areas in a display area of the display device according to one or more embodiments.

Referring to FIG. 4, the display device 10 may include a plurality of pixels PX in the display area DA. The plurality of pixels PX may include first to sixth pixels PX1, PX2, PX3, PX4, PX5, and PX6. The first pixel PX1, the second pixel PX2, and the third pixel PX3 may be side by side in the first direction DR1, and the fourth pixel PX4, the fifth pixel PX5, and the sixth pixel PX6 may be side by side in the first direction DR1. The first pixel PX1 and the fourth pixel PX4 may be side by side in the second direction DR2, the second pixel PX2 and the fifth pixel PX5 may be side by side in the second direction DR2, and the third pixel PX3 and the sixth pixel PX6 may be side by side in the second direction DR2. The plurality of pixels PX may be repeatedly in the arrangement of FIG. 4 across the entire surface of the display area DA.

Each of the plurality of pixels PX may include a plurality of light emitting areas EA1, EA2, and EA3. For example, each of the plurality of pixels PX may include a first light emitting area EA1, a second light emitting area EA2, and a third light emitting area EA3. One pixel PX may include one first light emitting area EA1, one second light emitting area EA2, and one third light emitting area EA3. However, without being limited thereto, the number of light emitting areas EA1, EA2, and EA3 in the pixel PX may be suitably changed.

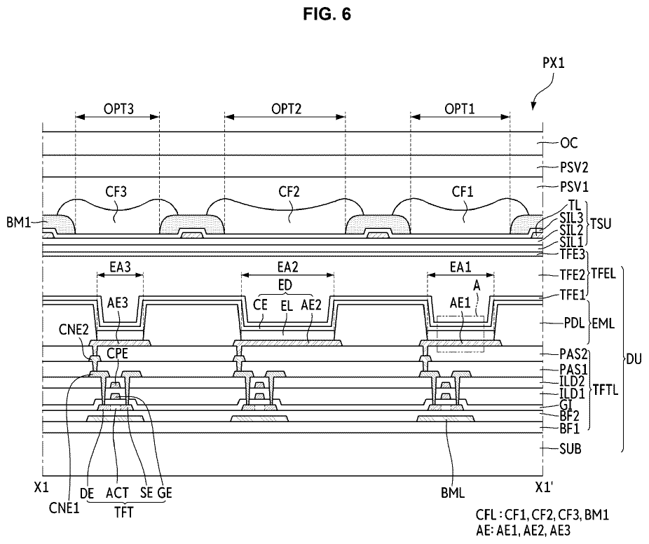

One pixel PX may include one or more light emitting elements ED (see FIG. 6). In some embodiments, one or more light emitting elements ED (see FIG. 6) included in one pixel PX may emit the same or different colors. For example, a light emitting element ED (see FIG. 6) in the first light emitting area EA1 may emit first light of a red color, a light emitting element ED (see FIG. 6) in the second light emitting area EA2 may emit second light of a green color, and a light emitting element ED (see FIG. 6) in the third light emitting area EA3 may emit third light of a blue color. However, the present disclosure is not limited thereto.

The respective light emitting areas EA1, EA2, and EA3 may emit light of different colors. For example, the first light emitting area EA1 may emit first light of a red color, the second light emitting area EA2 may emit second light of a green color, and the third light emitting area EA3 may emit third light of a blue color. However, the present disclosure is not limited thereto.

In one or more embodiments, each of the light emitting areas EA1, EA2, and EA3 of the display device 10 may be an area where a light emitting layer EL (see FIG. 6) overlaps a pixel electrode AE (see FIG. 6). For example, openings of a pixel defining film PDL (see FIG. 6) may correspond to the light emitting areas EA1, EA2, and EA3. For example, each of the light emitting areas EA1, EA2, and EA3 may be defined by a plurality of openings of the pixel defining film PDL (see FIG. 6) of the light emitting element layer EML. The first light emitting area EA1 may be an area where the light emitting layer EL (see FIG. 6) overlaps a first pixel electrode AE1 (see FIG. 6), the second light emitting area EA2 may be an area where the light emitting layer EL (see FIG. 6) overlaps a second pixel electrode AE2 (see FIG. 6), and the third light emitting area EA3 may be an area where the light emitting layer EL (see FIG. 6) overlaps a third pixel electrode AE3 (see FIG. 6).

In some embodiments, the plurality of light emitting areas EA1, EA2, and EA3 may be in a triangular shape. For example, the first light emitting area EA1 and the second light emitting area EA2 may be side by side in the second direction DR2, and the third light emitting area EA3 may be on one side in the first direction DR1 with respect to the first light emitting area EA1 and the second light emitting area EA2 and may be positioned between (approximately at the middle position of) the first light emitting area EA1 and the second light emitting area EA2 in the second direction DR2. For example, the third light emitting area EA3 may be in a diagonal direction with respect to the first light emitting area EA1 and the second light emitting area EA2.

However, the arrangement of the plurality of light emitting areas EA1, EA2, and EA3 is not limited thereto. For example, the plurality of light emitting areas EA1, EA2, and EA3 may be side by side in the first direction DR1 or the second direction DR2, or four light emitting areas may be in a PENTILE® form or structure, (e.g., an RGBG matrix, an RGBG structure, or an RGBG matrix structure), for example, a DIAMOND PIXEL™ form or structure, e.g., a display (e.g., an OLED display) containing red, blue, and green (RGB) light emitting regions provided in the shape of diamonds. PENTILER and DIAMOND PIXEL™ are trademarks owned by Samsung Display Co., Ltd. However, the disclosure is not limited thereto.

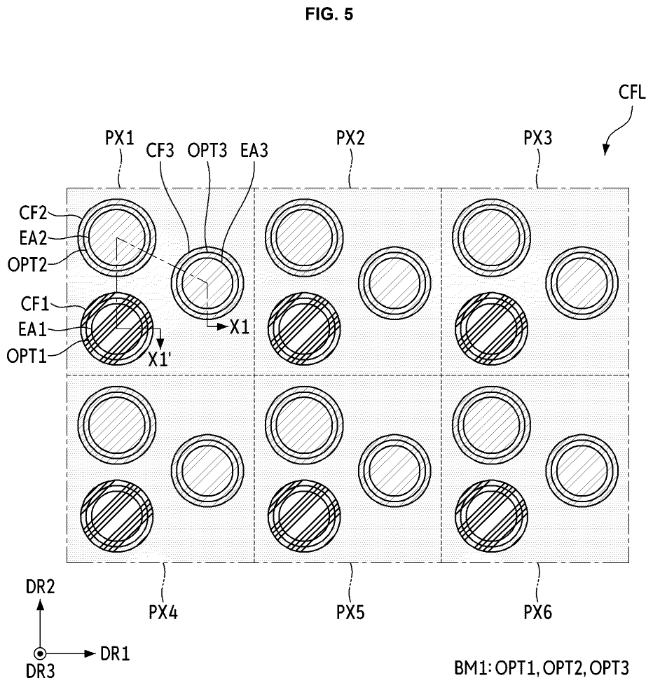

In one or more embodiments, the areas or sizes of the light emitting areas EA1, EA2, and EA3 may be different from each other. In the embodiment of FIG. 5, the area or size of the second light emitting area EA2 may be greater than the area or size of the first light emitting area EA1 and the area or size of the third light emitting area EA3, and the area or size of the first light emitting area EA1 may be greater than the area or size of the second light emitting area EA2. The intensity of light emitted may vary depending on the area of each of the light emitting areas EA1, EA2, and EA3, and a color of a screen displayed on the display device 10 or the electronic device 1 may be controlled by adjusting the area of each of the light emitting areas EA1, EA2, and EA3. It is illustrated in the embodiment of FIG. 4 that the area of the second light emitting area EA2 is the largest, but the present disclosure is not limited thereto. The size of each of the light emitting areas EA1, EA2, and EA3 and the area of the light emitting area may be freely adjusted according to the color of the screen required by the display device 10 and the electronic device 1. In addition, the area of each of the light emitting areas EA1, EA2, and EA3 may be related to light efficiency and lifespan of the light emitting element ED, and may have a trade-off relationship with reflection by external light. The area of each of the light emitting areas EA1, EA2, and EA3 may be adjusted in consideration of the herein-mentioned matters.

FIG. 5 is a plan view illustrating an arrangement of a color filter layer on the pixels and the light emitting areas of the display device according to one or more embodiments.

Referring to FIG. 5 in addition to FIG. 4, the display device 10 may include a first light blocking layer BM1 and a plurality of color filters CF1, CF2, and CF3 on the display area DA.

The first light blocking layer BM1 may be across the entire surface of the display area DA. The first light blocking layer BM1 may include a plurality of holes OPT1, OPT2, and OPT3 to correspond to the plurality of light emitting areas EA1, EA2, and EA3. The holes OPT1, OPT2, and OPT3 of the first light blocking layer BM1 may be respectively to correspond to the openings of the pixel defining film PDL (see FIG. 6). The first light blocking layer BM1 may cover the display area DA except for an area where the holes OPT1, OPT2, and OPT3 are in the display area DA. The holes OPT1, OPT2, and OPT3 of the first light blocking layer BM1 may be areas from which the light emitted from the light emitting areas EA1, EA2, and EA3 is emitted.

The plurality of holes OPT1, OPT2, and OPT3 may include a first hole OPT1 overlapping the first light emitting area EA1, a second hole OPT2 overlapping the second light emitting area EA2, and a third hole OPT3 overlapping the third light emitting area EA3.

Each of the plurality of holes OPT1, OPT2, and OPT3 may have a greater area on a plane than the area on a plane of each of the light emitting areas EA1, EA2, and EA3. For example, the first hole OPT1 may have a greater area on the plane than the first light emitting area EA1, the second hole OPT2 may have a greater area on the plane than the second light emitting area EA2, and the third hole OPT3 may have a greater area on the plane than the third light emitting area EA3.

In some embodiments, similarly to the arrangement of the light emitting areas EA1, EA2, and EA3, the holes OPT1, OPT2, and OPT3 may be in a triangular shape. The first hole OPT1 and the second hole OPT2 may be side by side in the second direction DR2, and the third hole OPT3 may be on one side in the first direction DR1 with respect to the first hole OPT1 and the second hole OPT2, and may be positioned between (approximately at the middle position of) the first hole OPT1 and the second hole OPT2 in the second direction DR2. For example, the third hole OPT3 may be in a diagonal direction with respect to the first hole OPT1 and the second hole OPT2.

However, the arrangement of the plurality of holes OPT1, OPT2, and OPT3 is not limited thereto. For example, the plurality of holes OPT1, OPT2, and OPT3 may be side by side in the first direction DR1 or the second direction DR2, or four holes may be in a PENTILE® form or structure, (e.g., an RGBG matrix, an RGBG structure, or an RGBG matrix structure), for example, a DIAMOND PIXEL™ form or structure, e.g., a display (e.g., an OLED display) containing red, blue, and green (RGB) light emitting regions provided in the shape of diamonds. PENTILER and DIAMOND PIXEL™ are trademarks owned by Samsung Display Co., Ltd. However, the disclosure is not limited thereto.

In one or more embodiments, each of the holes OPT1, OPT2, and OPT3 of the first light blocking layer BM1 may have a different area on the plane. As described herein, the area of each of the plurality of light emitting areas EA1, EA2, and EA3 may be different from each other, and accordingly, the sizes of the holes OPT1, OPT2, and OPT3 of the first light blocking layer BM1 may also be different from each other. For example, the diameter or size of the second hole OPT2 may be greater than that of the first hole OPT1 and the third hole OPT3, and the diameter or size of the first hole OPT1 may be greater than that of the third hole OPT3. However, the present disclosure is not limited thereto.

Each of the plurality of color filters CF1, CF2, and CF3 may be to correspond to the plurality of light emitting areas EA1, EA2, and EA3. For example, each of the plurality of color filters CF1, CF2, and CF3 may overlap the plurality of light emitting areas EA1, EA2, and EA3.

Each of the plurality of color filters CF1, CF2, and CF3 may be to correspond to the plurality of holes OPT1, OPT2, and OPT3 of the first light blocking layer BM1. For example, each of the plurality of color filters CF1, CF2, and CF3 may overlap the plurality of holes OPT1, OPT2, and OPT3 of the first light blocking layer BM1.

Each of the plurality of color filters CF1, CF2, and CF3 may completely cover the plurality of light emitting areas EA1, EA2, and EA3. Each of the plurality of color filters CF1, CF2, and CF3 may completely cover the plurality of holes OPT1, OPT2, and OPT3 of the first light blocking layer BM1. For example, each of the plurality of color filters CF1, CF2, and CF3 may have an area greater than the plurality of light emitting areas EA1, EA2, and EA3 and the plurality of holes OPT1, OPT2, and OPT3 of the first light blocking layer BM1. Therefore, each of the plurality of color filters CF1, CF2, and CF3 may completely cover an area where the light emitted from the light emitting areas EA1, EA2, and EA3 is output through the plurality of holes OPT1, OPT2, and OPT3 of the first light blocking layer BM1.

The color filters CF1, CF2, and CF3 may include a first color filter CF1, a second color filter CF2, and a third color filter CF3 to respectively correspond to different light emitting areas EA1, EA2, and EA3. The color filters CF1, CF2, and CF3 may include a colorant such as a dye or pigment that absorbs light in a wavelength band other than light in a selected wavelength band, and may be to correspond to the color of light emitted by the light emitting element including the light emitting areas EA1, EA2, and EA3. For example, the first color filter CF1 may be a red color filter that is to overlap the first light emitting area EA1 and transmits only first light of a red color, the second color filter CF2 may be a green color filter that is to overlap the second light emitting area EA2 and transmits only second light of a green color, and the third color filter CF3 may be a blue color filter that is to overlap the third light emitting area EA3 and transmits only third light of a blue color.

In some embodiments, similarly to the arrangement of the light emitting areas EA1, EA2, and EA3, the color filters CF1, CF2, and CF3 may be in a triangular shape. The first color filter CF1 and the second color filter CF2 may be side by side in the second direction DR2, and the third color filter CF3 may be on one side in the first direction DR1 with respect to the first color filter CF1 and the second color filter CF2, and may be positioned between (approximately at the middle position of) the first color filter CF1 and the second color filter CF2 in the second direction DR2. For example, the third color filter CF3 may be in a diagonal direction with respect to the first color filter CF1 and the second color filter CF2.

However, the arrangement of the plurality of color filters CF1, CF2, and CF3 is not limited thereto. For example, the plurality of color filters CF1, CF2, and CF3 may be side by side in the first direction DR1 or the second direction DR2, or four color filters may be in a PENTILE® form or structure, (e.g., an RGBG matrix, an RGBG structure, or an RGBG matrix structure), for example, a DIAMOND PIXEL™ form or structure, e.g., a display (e.g., an OLED display) containing red, blue, and green (RGB) light emitting regions provided in the shape of diamonds. PENTILE® and DIAMOND PIXEL™ are trademarks owned by Samsung Display Co., Ltd. However, the disclosure is not limited thereto.

In one or more embodiments, each of the plurality of color filters CF1, CF2, and CF3 may have a different size or area on the plane. As described herein, the size or area of each of the plurality of light emitting areas EA1, EA2, and EA3 may be different, and accordingly, the sizes or areas on the plane of the plurality of color filters CF1, CF2, and CF3 may also be different. For example, the size or area of the second color filter CF2, which is the green color filter, may be greater than the size or area of the first color filter CF1, which is the red color filter, and the third color filter CF3, which is the blue color filter. In addition, the size or area of the first color filter CF1 may be greater than the size or area of the third color filter CF3.

FIG. 6 is a cross-sectional view taken along line X1-X1′ of FIG. 5.

Referring to FIG. 6, in addition to FIGS. 4 and 5, the display panel 100 of the display device 10 may include a display layer DU, a touch sensing layer TSU, a color filter layer CFL, passivation layers PSV1 and PSV2, and an overcoat layer OC. The display layer DU may include a substrate SUB, a thin film transistor layer TFTL, a light emitting element layer EML, and an encapsulation layer TFEL. The color filter layer CFL may include a first light blocking layer BM1 and color filters CF1, CF2, and CF3. The substrate SUB may be a base substrate or a base member. The substrate SUB may be a flexible substrate that may be bent, folded, rolled, or the like. For example, the substrate SUB may include a polymer resin such as polyimide PI, but is not limited thereto. As another example, the substrate SUB may include a glass material or a metal material.

The thin film transistor layer TFTL may include a first buffer layer BF1, a lower metal layer BML, a second buffer layer BF2, a thin film transistor TFT, a gate insulating layer GI, a first interlayer insulating layer ILD1, a capacitor electrode CPE, a second interlayer insulating layer ILD2, a first connection electrode CNE1, a first passivation layer PAS1, a second connection electrode CNE2, and a second passivation layer PAS2.

The first buffer layer BF1 may be on the substrate SUB. The first buffer layer BF1 may include an inorganic film capable of preventing permeation of air or moisture. For example, the first buffer layer BF1 may include a plurality of inorganic films alternately stacked.

The lower metal layer BML may be on the first buffer layer BF1. For example, the lower metal layer BML may be formed of a single layer or a multi-layer made of any one of (e.g., selected from among) molybdenum (Mo), aluminum (Al), chromium (Cr), gold (Au), titanium (Ti), nickel (Ni), neodymium (Nd), and copper (Cu), or an alloy thereof.

The second buffer layer BF2 may cover the first buffer layer BF1 and the lower metal layer BML. The second buffer layer BF2 may include an inorganic film capable of preventing permeation of air and/or moisture. For example, the second buffer layer BF2 may include a plurality of inorganic films alternately stacked.

The thin film transistor TFT may be on the second buffer layer BF2, and may constitute a pixel circuit of each of the plurality of pixels. For example, the thin film transistor TFT may be a driving transistor or a switching transistor of the pixel circuit. The thin film transistor TFT may include a semiconductor layer ACT, a source electrode SE, a drain electrode DE, and a gate electrode GE.

The semiconductor layer ACT may be on the second buffer layer BF2. The semiconductor layer ACT may overlap the lower metal layer BML and the gate electrode GE in the thickness direction, and may be insulated from the gate electrode GE by the gate insulating layer GI. In a portion of the semiconductor layer ACT, a material of the semiconductor layer ACT may become a conductor to form the source electrode SE and the drain electrode DE.

The gate electrode GE may be on the gate insulating layer GI. The gate electrode GE may overlap the semiconductor layer ACT with the gate insulating layer GI interposed therebetween.

The gate insulating layer GI may be on the semiconductor layer ACT. For example, the gate insulating layer GI may cover the semiconductor layer ACT and the second buffer layer BF2, and may insulate the semiconductor layer ACT and the gate electrode GE from each other. The gate insulating layer GI may include a contact hole through which the first connection electrode CNE1 penetrates.

The first interlayer insulating layer ILD1 may cover the gate electrode GE and the gate insulating layer GI. The first interlayer insulating layer ILD1 may include a contact hole through which the first connection electrode CNE1 penetrates. The contact hole of the first interlayer insulating layer ILD1 may be coupled (e.g., connected) to the contact hole of the gate insulating layer GI and a contact hole of the second interlayer insulating layer ILD2.

The capacitor electrode CPE may be on the first interlayer insulating layer ILD1. The capacitor electrode CPE may overlap the gate electrode GE in the thickness direction. The capacitor electrode CPE and the gate electrode GE may form a capacitance.

The second interlayer insulating layer ILD2 may cover the capacitor electrode CPE and the first interlayer insulating layer ILD1. The second interlayer insulating layer ILD2 may include a contact hole through which the first connection electrode CNE1 penetrates. The contact hole of the second interlayer insulating layer ILD2 may be coupled (e.g., connected) to the contact hole of the first interlayer insulating layer ILD1 and the contact hole of the gate insulating layer GI.

The first connection electrode CNE1 may be on the second interlayer insulating layer ILD2. The first connection electrode CNE1 may electrically connect the drain electrode DE of the thin film transistor TFT and the second connection electrode CNE2 to each other. The first connection electrode CNE1 may be inserted into the contact holes formed in the second interlayer insulating layer ILD2, the first interlayer insulating layer ILD1, and the gate insulating layer GI to be in contact with the drain electrode DE of the thin film transistor TFT.

The first passivation layer PAS1 may cover the first connection electrode CNE1 and the second interlayer insulating layer ILD2. The first passivation layer PAS1 may protect the thin film transistor TFT. The first passivation layer PAS1 may include a contact hole through which the second connection electrode CNE2 penetrates.

The second connection electrode CNE2 may be on the first passivation layer PAS1. The second connection electrode CNE2 may electrically connect the first connection electrode CNE1 and a pixel electrode AE of a light emitting element ED to each other. The second connection electrode CNE2 may be inserted into the contact hole formed in the first passivation layer PAS1 and be in contact with the first connection electrode CNE1.

The second passivation layer PAS2 may cover the second connection electrode CNE2 and the first passivation layer PAS1. The second passivation layer PAS2 may include a contact hole through which the pixel electrode AE of the light emitting element ED penetrates.

The light emitting element layer EML may be on the thin film transistor layer TFTL. The light emitting element layer EML may include a light emitting element ED and a pixel defining film PDL. The light emitting element ED may include a pixel electrode AE, a light emitting layer EL, and a common electrode CE.

The pixel electrode AE may be on the second passivation layer PAS2. Different pixel electrodes AE may be each to overlap one of different openings of the pixel defining film PDL. The pixel electrode AE may be electrically coupled (e.g., connected) to the drain electrode DE of the thin film transistor TFT through the first and second connection electrodes CNE1 and CNE2.

The light emitting layer EL may be on the pixel electrode AE. For example, the light emitting layer EL may be an organic light emitting layer made of an organic material, but is not limited thereto. In the case in which the light emitting layer EL corresponds to the organic light emitting layer, when the thin film transistor TFT applies a predetermined voltage to the pixel electrode AE of the light emitting element ED and the common electrode CE of the light emitting element ED receives a common voltage or a cathode voltage, each of the holes and electrons may move to the light emitting layer EL through the hole transporting layer and the electron transporting layer, and the holes and electrons may be bonded to each other in the light emitting layer EL to emit light.

In one or more embodiments, the light emitting layers EL respectively on different pixel electrodes AE may emit light of different colors. For example, the light emitting layer on the first pixel electrode AE1 may emit red light of a first color, the light emitting layer on the second pixel electrode AE2 may emit green light of a second color, and the light emitting layer on the third pixel electrode AE3 may emit blue light of a third color. However, the present disclosure is not limited thereto. In another embodiment, the light emitting layer EL may be as a common layer on different pixel electrodes AE and the pixel defining film PDL. In this case, the display device 10 may further include a color adjustment layer on the light emitting elements ED.

The common electrode CE may be on the light emitting layer EL. For example, the common electrode CE may be implemented in the form of an electrode common to all pixels without being divided for each of the plurality of pixels. The common electrode CE may be on the light emitting layer EL in the pixel electrode AE, and may be on the pixel defining film PDL in an area other than the pixel electrode AE.

The common electrode CE may receive a common voltage or a low potential voltage. In the case in which the pixel electrode AE receives a voltage corresponding to the data voltage and the common electrode CE receives the low potential voltage, as a potential difference is formed between the pixel electrode AE and the common electrode CE, the light emitting layer EL may emit light.

The pixel defining film PDL including the plurality of openings may be on a portion of the second passivation layer PAS2 and the pixel electrode AE. Each opening in the pixel defining film PDL may expose a portion of the pixel electrode AE. As described herein, each of the openings of the pixel defining film PDL may define the first to third light emitting areas, and the first to third light emitting areas may have different areas or sizes. The pixel defining film PDL may separate and insulate the pixel electrodes AE of the plurality of light emitting elements ED from each other. The pixel defining film PDL may include a light absorbing material to prevent light reflection. For example, the pixel defining film PDL may include a polyimide (PI)-based binder, and a pigment in which red, green, and blue colors are mixed. Alternatively, the pixel defining film PDL may include a cardo-based binder resin, and a mixture of lactam black pigment and blue pigment. Alternatively, the pixel defining film PDL may include carbon black.

The encapsulation layer TFEL may be on the common electrode CE to cover the plurality of light emitting elements ED. The encapsulation layer TFEL may include at least one inorganic film to prevent oxygen or moisture from permeating into the light emitting element layer EML. The encapsulation layer TFEL may include at least one organic film to protect the light emitting element layer EML from foreign substances such as dust.

In one or more embodiments, the encapsulation layer TFEL may include a first encapsulation layer TFE1, a second encapsulation layer TFE2, and a third encapsulation layer TFE3. The first encapsulation layer TFE1 and the third encapsulation layer TFE3 may be inorganic encapsulation layers, and the second encapsulation layer TFE2 therebetween may be an organic encapsulation layer.

Each of the first encapsulation layer TFE1 and the third encapsulation layer TFE3 may include one or more inorganic insulating materials. The inorganic insulating material may include aluminum oxide, titanium oxide, tantalum oxide, hafnium oxide, zinc oxide, silicon oxide, silicon nitride, and/or silicon oxynitride.

The second encapsulation layer TFE2 may include a polymer-based material. Examples of the polymer-based material may include an acrylic resin, an epoxy-based resin, polyimide, polyethylene, and the like. For example, the second encapsulation layer TFE2 may include an acrylic resin, for example, polymethyl methacrylate or polyacrylic acid. The second encapsulation layer TFE2 may be formed by curing a monomer or applying a polymer.

In some embodiments, a refractive index of the second encapsulation layer TFE2 may be about 1.4 to 1.6. Preferably, the refractive index of the second encapsulation layer TFE2 may be approximately 1.5. In the present specification, the refractive index refers to an absolute refractive index measured using the D line (a wavelength λ is approximately 589 nanometer (nm): yellow) of natrium (or sodium) at room temperature and humidity (temperature 20±15° C., humidity 65±20%). For example, in the present specification, the refractive index may be an absolute refractive index measured at a wavelength of 589 nm according to the Cauchy Film Model using a refractive index meter (e.g., Ellipsometer (Ellipsometer M-2000, J. A. Woollam)) under 25° C. and a relative humidity of 65%.

The touch sensing layer TSU may be on the encapsulation layer TFEL. The touch sensing layer TSU may include a first touch insulating layer SIL1, a second touch insulating layer SIL2, a touch electrode TL, and a third touch insulating layer SIL3.

The first touch insulating layer SIL1 may be on the encapsulation layer TFEL. The first touch insulating layer SIL1 may have insulation and optical functions. The first touch insulating layer SIL1 may include at least one inorganic film. Optionally, the first touch insulating layer SIL1 may not be provided.

The second touch insulating layer SIL2 may cover the first touch insulating layer SIL1. In one or more embodiments, a touch electrode of another layer may be further on the first touch insulating layer SIL1, and the second touch insulating layer SIL2 may cover such a touch electrode TL. The second touch insulating layer SIL2 may have insulation and optical functions. For example, the second touch insulating layer SIL2 may be an inorganic film including at least one of (e.g., selected from among) a silicon nitride layer, a silicon oxy nitride layer, a silicon oxide layer, a titanium oxide layer, and an aluminum oxide layer.

A portion of the touch electrode TL may be on the second touch insulating layer SIL2. Each touch electrode TL may not overlap the pixel electrodes AE. Each touch electrode TL may be formed as a single layer made of molybdenum (Mo), titanium (Ti), copper (Cu), aluminum (AI), and/or indium tin oxide (ITO), or be formed as a stacked structure (Ti/Al/Ti) of aluminum and titanium, a stacked structure (ITO/AI/ITO) of aluminum and ITO, an APC alloy, and a stacked structure (ITO/APC/ITO) of an APC alloy and ITO.

The touch electrode TL of the touch sensing layer TSU may be to have a certain line width and overlap a first light blocking layer BM1 described later. The first light blocking layer BM1 may have a width sufficient to completely cover the touch electrode TL, and a gap between an edge of the first light blocking layer BM1 and the touch electrode TL may be defined. The touch electrode TL may be so that a center thereof is almost parallel to a center of the first light blocking layer BM1, and a gap from both sides (e.g., opposite sides) of the touch electrode TL to the edge of the first light blocking layer BM1 may be approximately constant.

The third touch insulating layer SIL3 may cover the touch electrode TL and the second touch insulating layer SIL2. The third touch insulating layer SIL3 may have insulation and optical functions. The third touch insulating layer SIL3 may be made of the materials illustrated in the second touch insulating layer SIL2.

The first light blocking layer BM1 may include a light absorbing material. For example, the first light blocking layer BM1 may include an inorganic black pigment or an organic black pigment. The inorganic black pigment may be carbon black, and the organic black pigment may include at least one of (e.g., selected from among) lactam black, perylene black, and aniline black, but is not limited thereto.

The first light blocking layer BM1 may be on the third touch insulating layer SIL3 of the touch sensing layer TSU. The first light blocking layer BM1 may be to cover a conductive line of the touch electrode TL, and may include a plurality of holes OPT1, OPT2, and OPT3 to overlap the pixel electrodes AE. For example, the first hole OPT1 may be to overlap the first pixel electrode AE1, the second hole OPT2 may be to overlap the second pixel electrode AE2, and the third hole OPT3 may be to overlap the third pixel electrode AE3. The areas or sizes of the respective holes OPT1, OPT2, and OPT3 may be greater than the areas or sizes of the pixel electrodes AE. In addition, the areas or sizes of the respective holes OPT1, OPT2, and OPT3 may be formed to be greater than the openings of the pixel defining film PDL, and the light emitted from the light emitting element ED may be viewed by a user not only from the front but also from the side of the display device 10.

The color filters CF1, CF2, and CF3 may be on the first light blocking layer BM1. The color filters CF1, CF2, and CF3 may be to correspond to the light emitting areas EA1, EA2, and EA3, respectively. For example, the first color filter CF1 may be to correspond to the first light emitting area EA1, the second color filter CF2 may be to correspond to the second light emitting area EA2, and the third color filter CF3 may be to correspond to the third light emitting area EA3. The color filters CF1, CF2, and CF3 may be to correspond to the holes OPT1, OPT2, and OPT3 of the first light blocking layer BM1. For example, the first color filter CF1 may be to correspond to the first hole OPT1, the second color filter CF2 may be to correspond to the second hole OPT2, and the third color filter CF3 may be to correspond to the third hole OPT3.

The passivation layers PSV1 and PSV2 may be on the first light blocking layer BM1 and the color filter layer CFL. The passivation layers PSV1 and PSV2 may be over an entire surface of the display area DA to planarize an upper surface of the display panel 100. The passivation layers PSV1 and PSV2 may include a first passivation layer PSV1 on the color filter layer CFL and the first light blocking layer BM1, and a second passivation layer PSV2 on the first passivation layer PSV1. The passivation layers PSV1 and PSV2 may be formed of a plurality of layers to planarize a step caused by the color filter layer CFL and the first light blocking layer BM1.

The passivation layers PSV1 and PSV2 may be colorless light-transmitting layers excluding (having no) color in a visible light band. For example, the passivation layers PSV1 and PSV2 may include a colorless light-transmitting organic material such as an acryl-based resin.

The overcoat layer OC may be on the passivation layers PSV1 and PSV2. The overcoat layer OC may be over the entire surface of the display area DA to planarize the upper surface of the display panel 100. The overcoat layer OC may be a colorless light-transmitting layer having no color in a visible light band. For example, the overcoat layer OC may include a colorless light-transmitting organic material such as an acryl-based resin.

The display device 10 according to the present embodiment may reduce reflected light due to external light by absorbing a portion of the light entering from the outside of the display device 10, because of including the color filter layer CFL. Therefore, the color filter layer CFL may prevent color distortion caused by reflection of external light. In addition, since there is no need to have a separate polarizing plate for reducing the reflection of external light, light emission efficiency of the display device 10 may be improved.

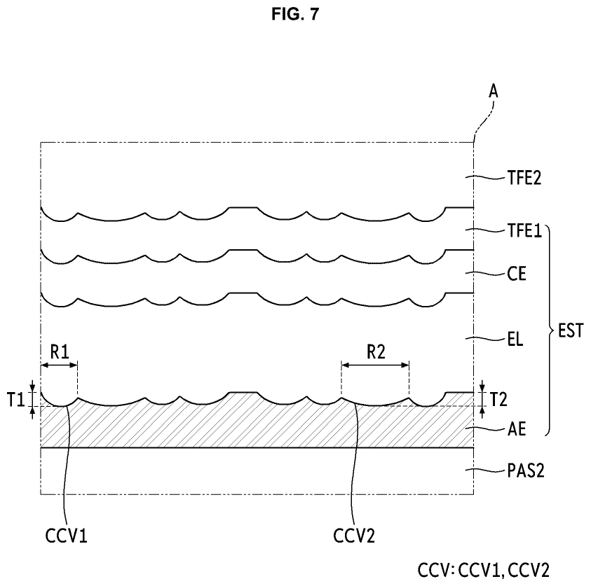

In some embodiments, the display device 10 according to the present embodiment may include concave portions CCV (see FIG. 7) in the pixel electrode AE and a light emitting stack EST (see FIG. 7) including the pixel electrode AE, to minimize an external light reflection diffraction phenomenon that occurs by the color filter layer CFL and the first light blocking layer BM1 in an off-state in which no image is displayed. This will be described later with reference to FIG. 7, and/or the like.

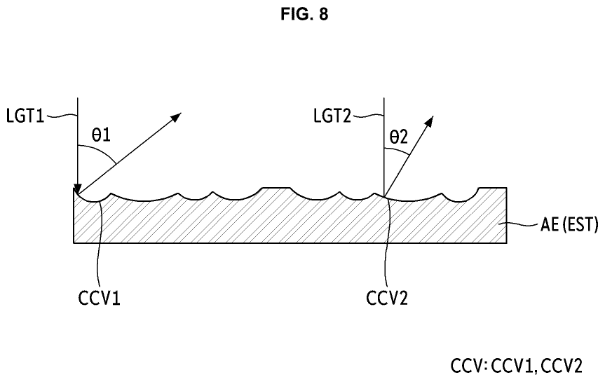

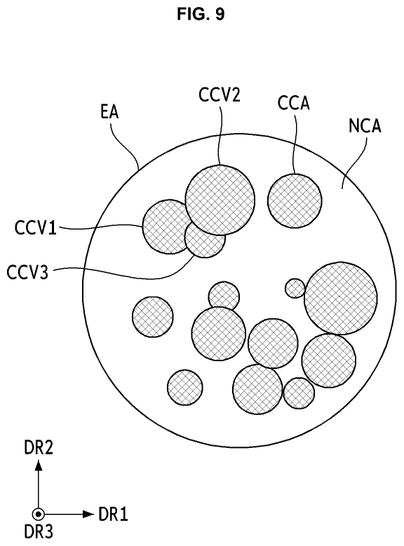

FIG. 7 is an enlarged cross-sectional view of area A of FIG. 6. FIG. 8 is a cross-sectional view for describing a difference in reflection angle according to a depth of a concave portion of the display device according to one or more embodiments. FIG. 9 is a plan view illustrating a concave area and a non-concave area in the light emitting area of the display device according to one or more embodiments.

Referring to FIGS. 7 to 9 in addition to FIGS. 4 to 6, the pixel electrode AE may include a plurality of concave portions CCV positioned on one surface of the pixel electrode AE. For example, the pixel electrode AE may include a plurality of concave portions CCV positioned on an upper surface of the pixel electrode AE (e.g., on a boundary surface between the pixel electrode AE and the light emitting layer EL).

In some embodiments, as the plurality of concave portions CCV are on one surface of the pixel electrode AE, a structure identical to the shape of the plurality of concave portions CCV may also be on one surface of the light emitting layer EL, the common electrode CE, and the first encapsulation layer TFE1 on the pixel electrode AE. For example, concave portions that are conformally formed along the shape of the plurality of concave portions CCV on one surface of the pixel electrode AE may further be on one surface of the light emitting layer EL, the common electrode CE, and the first encapsulation layer TFE1. The pixel electrode AE, the light emitting layer EL, the common electrode CE, and the first encapsulation layer TFE1 having the plurality of concave portions CCV and the structure as described herein may be defined as a light emitting stack EST. In this case, as with the pixel electrode AE, an upper surface of the light emitting stack EST may include a plurality of concave portions CCV. Since the second encapsulation layer TFE2 on the light emitting stack EST serves as a planarization film, an upper surface of the second encapsulation layer TFE2 may not include a concave portion CCV.

The plurality of concave portions CCV may each have the same or different sizes within a certain range. For example, some of the plurality of concave portions CCV may have different sizes, and other some thereof may have the same size.

In the present specification, the width or depth of the plurality of concave portions CCV may be collectively referred to as the size of the plurality of concave portions CCV. For example, the size of the plurality of concave portions CCV may include both (e.g., simultaneously) the width and the depth of the plurality of concave portions CCV, or may refer to either the width or the depth of the plurality of concave portions CCV.

In one or more embodiments, as illustrated in FIG. 7, the plurality of concave portions CCV may include a first concave portion CCV1 and a second concave portion CCV2. A first width R1 of the first concave portion CCV1 may be smaller than a second width R2 of the second concave portion CCV2. A first depth T1 of the first concave portion CCV1 may be greater than a second depth T2 of the second concave portion CCV2.

However, this is merely an example, and the plurality of concave portions CCV may include concave portions CCV with different widths and depths in addition to the first concave portion CCV1 and the second concave portion CCV2. In addition, since the width and depth of the plurality of concave portions CCV may have arbitrary values within a certain range, some concave portions CCV may have the same width and depth.

As illustrated in FIG. 8, an angle at which the reflected light is reflected may vary depending on the width and depth of the plurality of concave portions CCV. For example, first light LGT1 and second light LGT2, which are incident at the same frontal angle, may be incident on the first concave portion CCV1 and the second concave portion CCV2, respectively. A reflection angle θ1 of the first light LGT1 incident on the first concave portion CCV1 may be different from a reflection angle θ2 of the second light LGT2 incident on the second concave portion CCV2. Since a curvature of a reflective surface varies depending on the width and depth of the plurality of concave portions CCV, the angle at which the reflected light is reflected may vary.

As more light is reflected at different angles, the light is spread over a variety of ranges, which minimizes the external light reflection diffraction phenomenon. For example, as each of the plurality of concave portions CCV has a different width and depth, more light is reflected at different angles, so that the light is spread over a variety of ranges, thereby minimizing the external light reflection diffraction phenomenon.

The plurality of concave portions CCV may have the same or different widths and depths, but in some embodiments, the range of widths and depths of the plurality of concave portions CCV may be limited depending on a wavelength of light and a refractive index of an upper layer. For example, the width of the plurality of concave portions CCV may be approximately 2 micrometer (μm) to 6 μm. The depth of the plurality of concave portions CCV may be approximately 0.2 μm to 0.4 μm.

In some embodiments, a maximum value of the width of the plurality of concave portions CCV may be twice or more of a minimum value thereof. The range of widths of the plurality of concave portions CCV may be defined according to the following Equation 1. In the following Equation 1, Δx represents the range of widths of the plurality of concave portions CCV, A represents a wavelength of light, and e represents a diffraction angle.

$$θ = asin ( \frac{λ}{2 Δ x} ) \qquad Equation 1$$

According to Equation 1 herein, since the diffraction angle θ is proportional to the wavelength λ of light and the wavelength of visible light is approximately 380 nm to 780 nm, which is approximately twice, the range Δx of widths of the plurality of concave portions CCV may be approximately twice or more. Therefore, the maximum value of the width of the plurality of concave portions CCV may be twice or more of the minimum value thereof.

In some embodiments, since the range Δx of the widths of the plurality of concave portions CCV is affected by the wavelength λ of light, the range Δx of the widths of the plurality of concave portions CCV in each of the first to third light emitting areas EA1, EA2, and EA3 may be different from each other. For example, the range Δx of the widths of the plurality of concave portions CCV in the first light emitting area EA1 that emits red light may be approximately 3 μm to 6 μm, the range Δx of the widths of the plurality of concave portions CCV in the second light emitting area EA2 that emits green light may be approximately 2.5 μm to 5 μm, and the range Δx of the widths of the plurality of concave portions CCV in the third light emitting area EA3 that emits blue light may be approximately 2.2 μm to 4.4 μm.

In the present specification, the different range of widths refers to that even if some ranges overlap and include the same value, the minimum and maximum values of the widths are different, so that at least some ranges include different values. For example, the different range of widths refers to that even if the widths of the plurality of concave portions CCV in each of the first to third light emitting areas EA1, EA2, and EA3 may be partially the same, the minimum and maximum values of the widths of the plurality of concave portions CCV in each of the first to third light emitting areas EA1, EA2, and EA3 are different, so that the width that the plurality of concave portions CCV of one light emitting area EA may have includes a width that the plurality of concave portions CCV of the remaining light emitting areas EA may not have.

In some embodiments, the depth of the plurality of concave portions CCV may be defined according to the following Equation 2. In the following Equation 2, Δφ represents a phase difference, λ represents a wavelength of light, n represents a refractive index of an upper layer, and d represents a depth of the plurality of concave portions CCV. The coefficient of d, 2, is the product of the number of round trips, because the external light is incident on the light emitting stack EST and then reflected.

$$Δ∅ = \vert \frac{2 π}{λ} n 2 d \vert \qquad Equation 2$$

The phase difference Δφ at which the degree of diffusion of reflected light is maximum may be 2π. Since the wavelength λ of light is the wavelength of visible light, it is approximately 380 nm to 780 nm, and since the refractive index of the second encapsulation layer TFE2, which is the upper layer of the light emitting stack EST, is approximately 1.4 to 1.6, the range of the depth d of the plurality of concave portions CCV may be approximately 0.2 μm to 0.4 μm.

Each pixel PX may include a plurality of concave portions CCV of different patterns. Within one pixel PX, each light emitting area EA may include a plurality of concave portions CCV of different patterns. Two different portions of the light emitting area EA within one light emitting area EA may include a plurality of concave portions CCV of different patterns.

In the present specification, the meaning of the plurality of concave portions CCV of different patterns includes a case where the arrangements of the plurality of concave portions CCV are different from each other, a case where the sizes of the plurality of concave portions CCV are different from each other, or a case where both (e.g., simultaneously) are present. The fact that the arrangements of the plurality of concave portions CCV are different from each other refers to that the plurality of concave portions CCV are non-periodically or irregularly disposed, and the fact that the sizes of the plurality of concave portions CCV are different from each other refers to that the sizes of the plurality of concave portions CCV are non-periodically or irregularly formed.

In the following, the case where each pixel PX includes the plurality of concave portions CCV of different patterns, the case where each light emitting area EA within one pixel PX includes the plurality of concave portions CCV of different patterns, and the case where two different portions of the light emitting area EA within one light emitting area EA include the plurality of concave portions CCV of different patterns will be separately described.

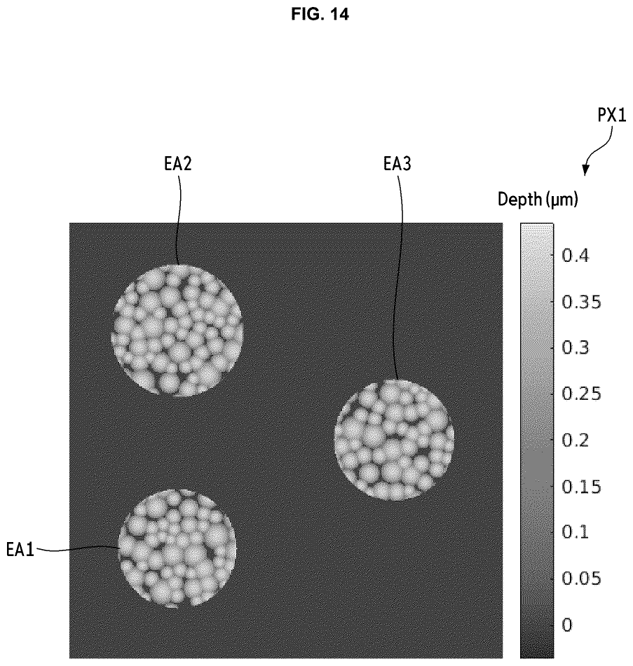

First, each pixel PX may include a plurality of concave portions CCV of different patterns. For example, the patterns of the plurality of concave portions CCV included in different pixels PX may be different from each other. For example, each pixel PX may include a plurality of concave portions CCV of different patterns, such as the first to fourth pixels PX1 to PX4 illustrated in FIGS. 14, 17, 20, and 23 described herein, respectively. In particular, the patterns of the plurality of concave portions CCV included in the same first to third light emitting areas EA1, EA2, and EA3 of each pixel PX may be different from each other. Accordingly, external light reflected from the same first to third light emitting areas EA1, EA2, and EA3 of each pixel PX may be prevented from being diffracted by each other.

For example, as illustrated in FIG. 4, each of the plurality of pixels PX may include a plurality of light emitting areas EA. In the plurality of pixels PX, the plurality of light emitting areas EA may have the same arrangement. For example, the arrangement of the first to third light emitting areas EA1, EA2, and EA3 in the first pixel PX1 may be the same as the arrangement of the first to third light emitting areas EA1, EA2, and EA3 in the second pixel PX2.

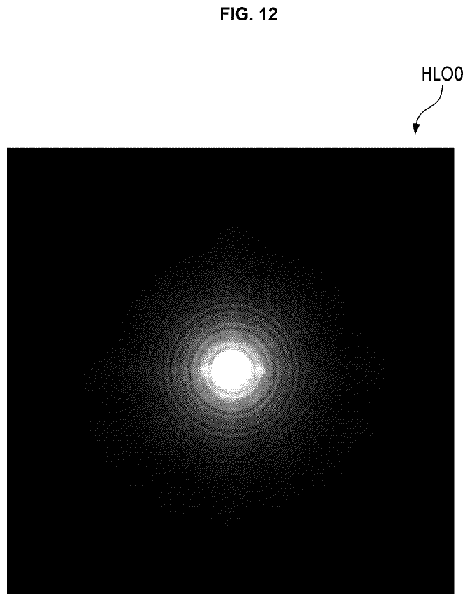

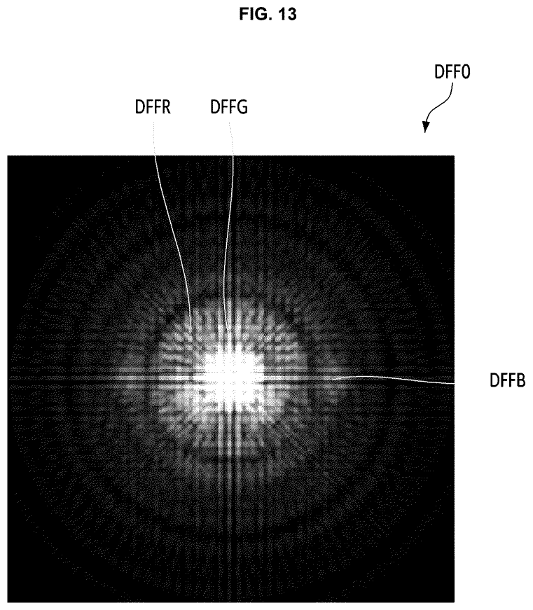

In this way, as the plurality of pixels PX include the plurality of light emitting areas EA that are regularly arranged, a reflection diffraction pattern described later in FIGS. 12 and 13 may occur when external light is reflected from the display device 10. For example, as the first light emitting area EA1 of the first pixel PX1 and the first light emitting area EA1 of the second pixel PX2 that emit the same color cause constructive interference, the second light emitting area EA2 of the first pixel PX1 and the second light emitting area EA2 of the second pixel PX2 that emit the same color cause constructive interference, and the third light emitting area EA3 of the first pixel PX1 and the third light emitting area EA3 of the second pixel PX2 that emit the same color cause constructive interference, the reflection diffraction patterns illustrated in FIGS. 12 and 13 having regular patterns may be formed.

In the display device 10 according to the present embodiment, as each pixel PX includes the plurality of concave portions CCV of different patterns, the external light reflected from the same first to third light emitting areas EA1, EA2, and EA3 of each pixel PX may be irregularly reflected, thereby minimizing the reflection diffraction phenomenon.

Next, within one pixel PX, each light emitting area EA may include a plurality of concave portions CCV of different patterns. For example, the patterns of the plurality of concave portions CCV each included in different light emitting areas EA within one pixel PX may be different from each other. For example, as in the first pixel PX1 illustrated in FIG. 14 described later, the pattern of the plurality of concave portions CCV included in the first light emitting area EA1 within the first pixel PX1, the pattern of the plurality of concave portions CCV included in the second light emitting area EA2 within the first pixel PX1, and the pattern of the plurality of concave portions CCV included in the third light emitting area EA3 within the first pixel PX1 may be different from each other. Accordingly, the external light reflected from the same first to third light emitting areas EA1, EA2, and EA3 of each pixel PX may be prevented from being separated into a selected color and diffracted.

For example, as described herein with reference to Equations 1 and 2, since the first to third light emitting areas EA1, EA2, and EA3 are configured to emit light having different wavelengths, the diffraction angle or phase difference of the external light reflected from each of the first to third light emitting areas EA1, EA2, and EA3 may be different. In this case, as in the reflection diffraction pattern illustrated in FIGS. 12 and 13, the external light may be separated into colors that the first to third light emitting areas EA1, EA2, and EA3 are configured to emit, thereby forming a reflection diffraction pattern having a regular pattern.

In the display device 10 according to the present embodiment, since each light emitting area EA includes the plurality of concave portions CCV of different patterns within one pixel PX, the external light reflected from each light emitting area EA within one pixel PX may be irregularly reflected, thereby minimizing the reflection diffraction phenomenon.

Next, two different portions of the light emitting area EA within one light emitting area EA may include a plurality of concave portions CCV of different patterns. For example, the patterns of the plurality of concave portions CCV included in two different portions of the light emitting area EA within one light emitting area EA may be different from each other. For example, as illustrated in FIG. 9, a pattern of a plurality of concave portions CCV included in a first portion of the first light emitting area EA1 within the first light emitting area EA1 of the first pixel PX1 may be different from a pattern of a plurality of concave portions CCV included in a second portion of the first light emitting area EA1 within the first light emitting area EA1 of the first pixel PX1. The first portion and the second portion of the first light emitting area EA1 refer to different arbitrary areas included in the first light emitting area EA1.

In the display device 10 according to the present embodiment, as two different portions of the light emitting area EA within one light emitting area EA include the plurality of concave portions CCV of different patterns, external light reflected from two different portions of the light emitting area EA within one light emitting area EA may be irregularly reflected, thereby minimizing the reflection diffraction phenomenon.

In some embodiments, to determine whether the plurality of concave portions CCV having the same or different widths or depths are non-periodically or irregularly between the pixels PX, between the light emitting areas EA within one pixel PX, or between two different portions of the light emitting area EA within one light emitting area EA, an average value of the widths or depths of the plurality of concave portions CCV in a selected area may be used.

The case where the plurality of concave portions CCV are non-periodically or irregularly between two different portions of the light emitting area EA within one light emitting area EA will be described as an example. For example, in the light emitting area EA illustrated as an example in FIG. 9, the light emitting area EA may be divided into four equal portions in the first direction DR1 and the second direction DR2, and the average value of the widths or depths of the plurality of concave portions CCV in each quadrant may be measured. When the plurality of concave portions CCV having the same or different widths or depths are non-periodically or irregularly within the light emitting area EA, the average value of the widths or depths of the plurality of concave portions CCV in each quadrant may be different from each other. For example, the example of dividing the light emitting area EA into four equal portions is described, but as the number of divisions of the light emitting area EA increases and the numerical values of the average value in each divided area have different values, it may be determined that the plurality of concave portions CCV having the same or different widths or depths are non-periodically or irregularly within the light emitting area EA.

In this way, as the plurality of concave portions CCV are arbitrarily within the light emitting area EA, the amount of light reflected at different angles increases, so that the light is spread over a variety of ranges, thereby minimizing the external light reflection diffraction phenomenon.

The case where the plurality of concave portions CCV are non-periodically or irregularly between two different portions of the light emitting area EA within the light emitting area EA has been described as an example, but the external light reflection diffraction phenomenon may be minimized in the same manner even in the case where the plurality of concave portions CCV are non-periodically or irregularly between the pixels PX or between the light emitting areas EA within one pixel PX.

Alternatively, in some embodiments, to determine whether the plurality of concave portions CCV having the same or different widths or depths are non-periodically or irregularly between the pixels PX, between the light emitting areas EA within one pixel PX, or between two different portions of the light emitting area EA within one light emitting area EA, the number of the plurality of concave portions CCV in a selected area may be used.

The case where the plurality of concave portions CCV are non-periodically or irregularly between two different portions of the light emitting area EA within one light emitting area EA will be described as an example. For example, in the light emitting area EA illustrated as an example in FIG. 9, the light emitting area EA may be divided into four equal portions in the first direction DR1 and the second direction DR2, and the number of the plurality of concave portions CCV in each quadrant may be measured. When the plurality of concave portions CCV are non-periodically or irregularly within the light emitting area EA, the number of the plurality of concave portions CCV in each quadrant may be different from each other. For example, the example of dividing the light emitting area EA into four equal portions is described, but as the number of divisions of the light emitting area EA increases and the number of the plurality of concave portions CCV in each quadrant has different values, it may be determined that the plurality of concave portions CCV are non-periodically or irregularly within the light emitting area EA.

However, since the plurality of concave portions CCV are non-periodically or irregularly disposed, some of the divided portions may include the same number of the plurality of concave portions CCV, depending on the position and number of divisions of the light emitting area EA. Even though some of the divided portions include the same number of the plurality of concave portions CCV, it may be determined that the plurality of concave portions CCV are non-periodically or irregularly within the light emitting area EA, as the divided portion in which the number of the plurality of concave portions CCV has different values increases.

The case where the plurality of concave portions CCV are non-periodically or irregularly between two different portions of the light emitting area EA within the light emitting area EA has been described as an example, but the external light reflection diffraction phenomenon may be minimized in the same manner even in the case where the plurality of concave portions CCV are non-periodically or irregularly between the pixels PX or between the light emitting areas EA within one pixel PX.

In some embodiments, the light emitting area EA may include a concave area CCA in which the concave portion CCV is and a non-concave area NCA in which the concave portion CCV is not in plan view. As an area of the concave area CCA relative to the total area of the light emitting area EA increases, the spread range of reflected light becomes more diverse, thereby minimizing the external light reflection diffraction phenomenon. The area of the concave area CCA relative to the total area of the light emitting area EA may be defined as a fill factor, and as a value of the fill factor increases, the spread range of reflected light becomes more diverse, thereby minimizing the external light reflection diffraction phenomenon.

In some embodiments, to increase the value of the fill factor, the plurality of concave portions CCV may at least partially overlap each other in plan view. For example, as illustrated in FIG. 9, the first concave portion CCV1, the second concave portion CCV2, and the third concave portion CCV3 may each be circular or elliptical, and the centers of the first concave portion CCV1, the second concave portion CCV2, and the third concave portion CCV3 may be positioned at different positions. However, since the width of each of the first concave portion CCV1, the second concave portion CCV2, and the third concave portion CCV3 is greater than a distance between the centers of each of the first concave portion CCV1, the second concave portion CCV2, and the third concave portion CCV3, the first concave portion CCV1, the second concave portion CCV2, and the third concave portion CCV3 may at least partially overlap each other in a plan view.

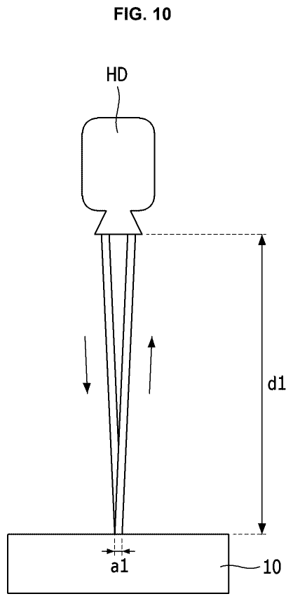

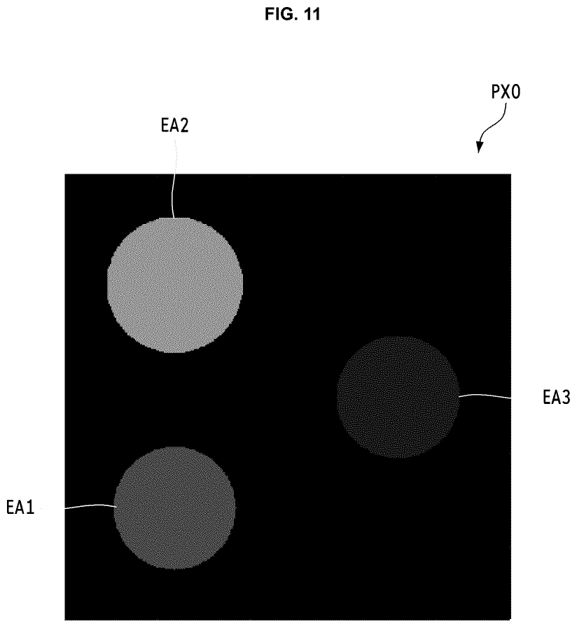

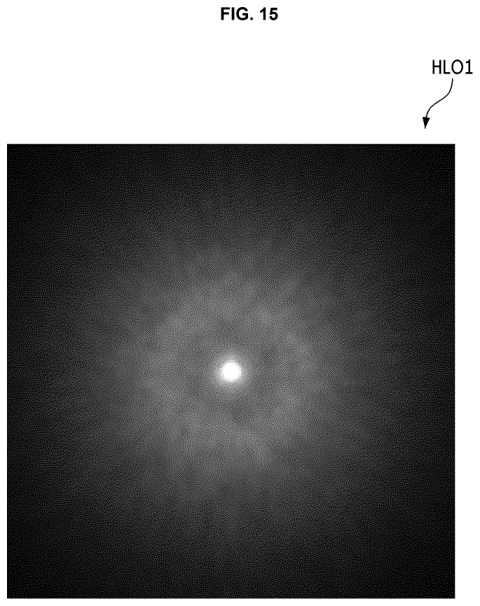

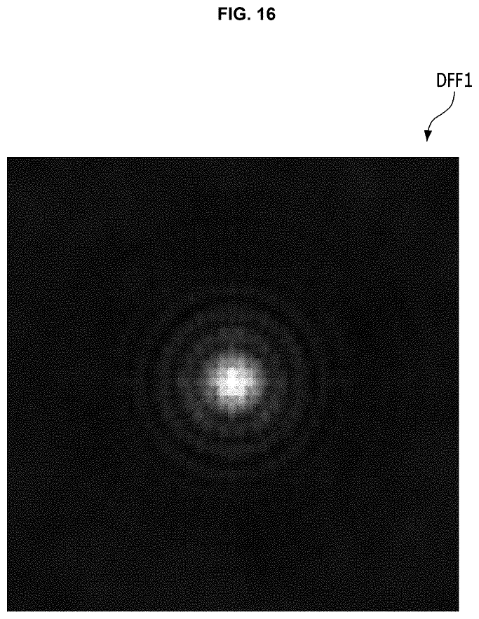

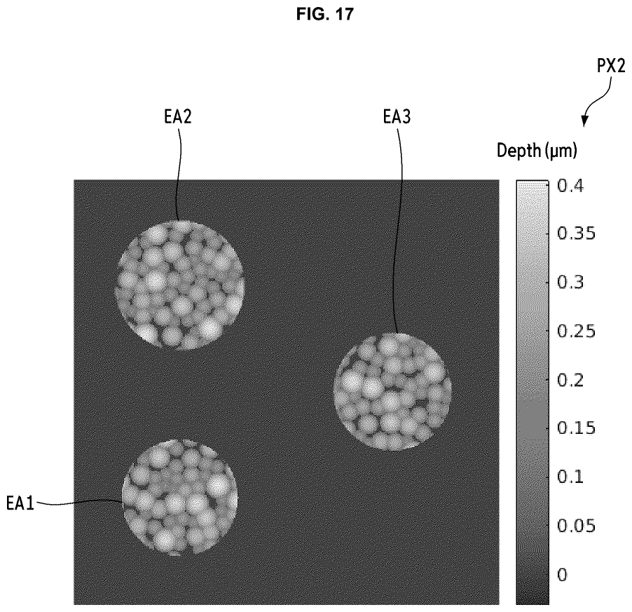

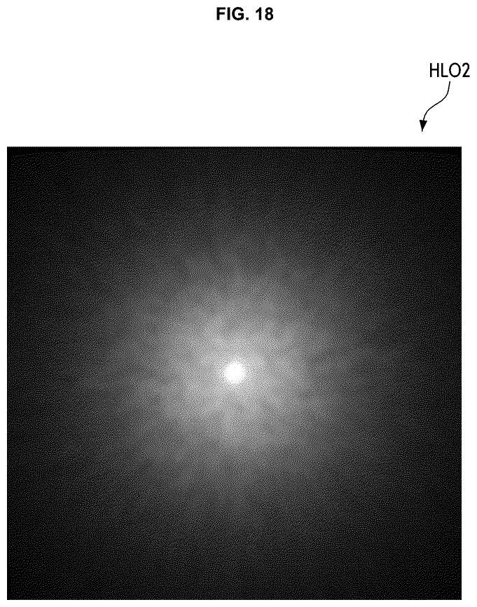

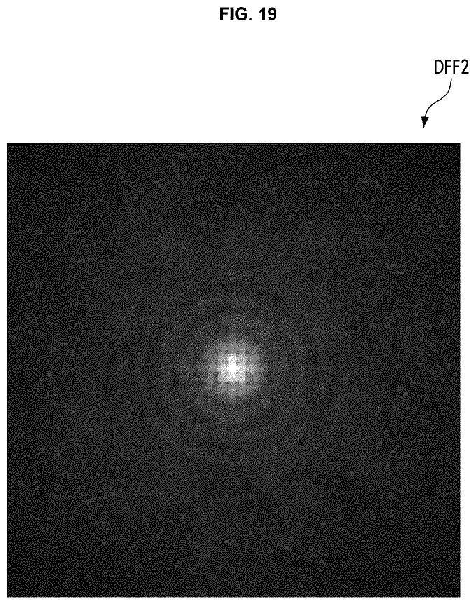

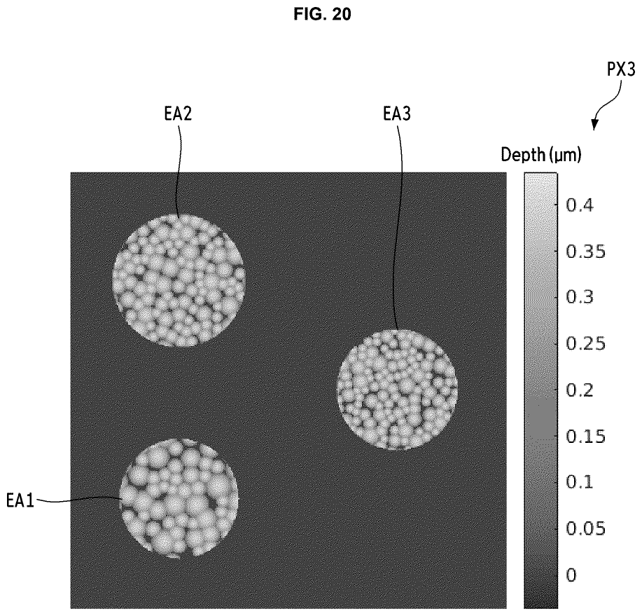

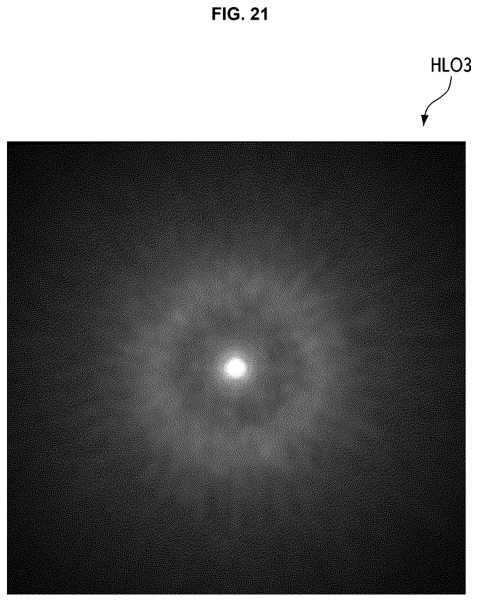

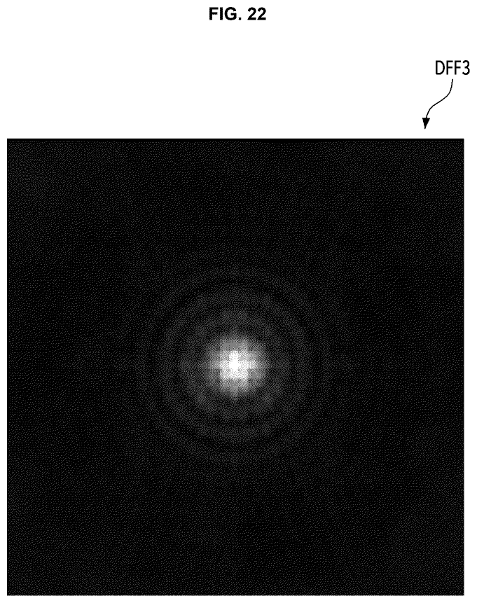

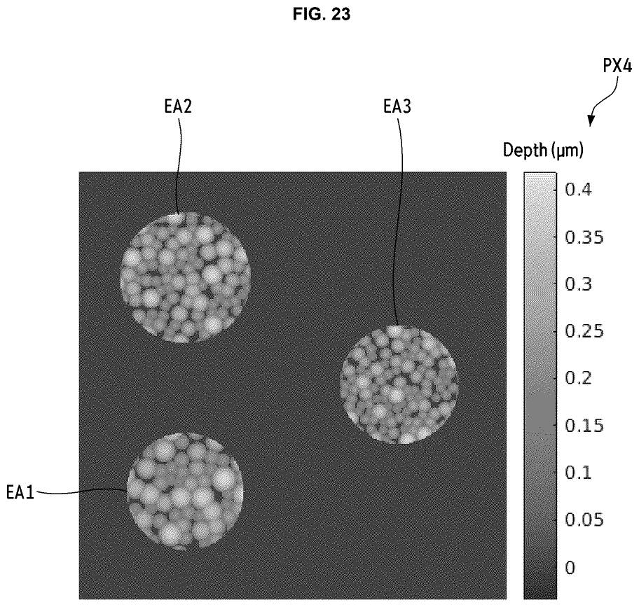

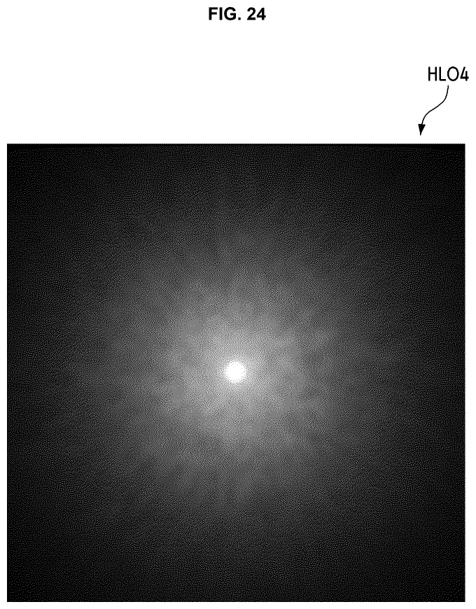

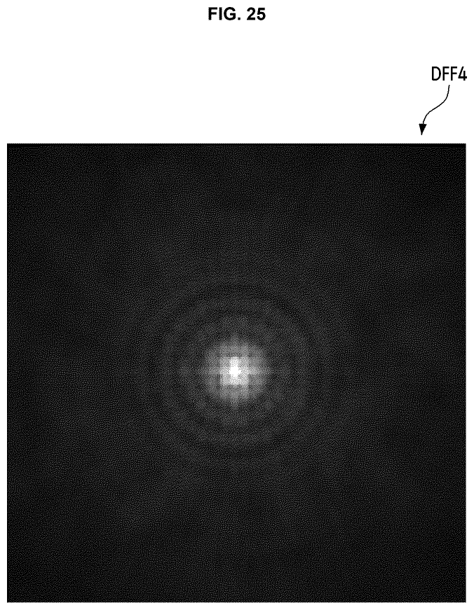

FIG. 10 is a side view illustrating an experiment measuring reflection diffraction characteristics of the display device according to one or more embodiments. FIG. 11 is a plan view illustrating a pixel according to a comparative example. FIG. 12 is a photograph illustrating a halo pattern among the reflection diffraction characteristics of the pixel according to the comparative example. FIG. 13 is a photograph illustrating a diffraction pattern among the reflection diffraction characteristics of the pixel according to the comparative example. FIG. 14 is a plan view illustrating a pixel according to a first embodiment. FIG. 15 is a photograph illustrating a halo pattern among the reflection diffraction characteristics of the pixel according to the first embodiment. FIG. 16 is a photograph illustrating a diffraction pattern among the reflection diffraction characteristics of the pixel according to the first embodiment. FIG. 17 is a plan view illustrating a pixel according to a second embodiment. FIG. 18 is a photograph illustrating a halo pattern among the reflection diffraction characteristics of the pixel according to the second embodiment. FIG. 19 is a photograph illustrating a diffraction pattern among the reflection diffraction characteristics of the pixel according to the second embodiment. FIG. 20 is a plan view illustrating a pixel according to a third embodiment. FIG. 21 is a photograph illustrating a halo pattern among the reflection diffraction characteristics of the pixel according to the third embodiment. FIG. 22 is a photograph illustrating a diffraction pattern among the reflection diffraction characteristics of the pixel according to the third embodiment. FIG. 23 is a plan view illustrating a pixel according to a fourth embodiment. FIG. 24 is a photograph illustrating a halo pattern among the reflection diffraction characteristics of the pixel according to the fourth embodiment. FIG. 25 is a photograph illustrating a diffraction pattern among the reflection diffraction characteristics of the pixel according to the fourth embodiment.

Referring to FIGS. 10 to 25 in addition to FIGS. 5 to 7, an experiment of measuring the reflection diffraction characteristics of the display device 10 may be performed by irradiating light onto the display device 10. For example, as illustrated in FIG. 10, a light source head HD may irradiate a light source having a diameter a1 of approximately 0.1 centimeter (cm) onto the display device 10 from a certain distance d1. A surface onto which the light source is incident may be a light emitting surface of the display device 10.

Depending on the distance d1 between the light source head HD and the display device 10, the type (kind) of pattern that occurs according to reflection diffraction may be different. For example, the type (kind) of pattern that occurs when the distance d1 is approximately 10 cm may be a halo pattern, and the type (kind) of pattern that occurs when the distance d1 is approximately 30 cm may be a diffraction pattern. The halo pattern may be the patterns illustrated in FIGS. 12, 15, 18, 21, and 24, and the diffraction pattern may be the patterns illustrated in FIGS. 13, 16, 19, 22, and 25.

As illustrated in FIG. 11, a pixel PX0 of the display device 10 according to the comparative example may not include a concave portion CCV within the light emitting areas EA. When the pixel does not include the concave portion CCV, a diffraction phenomenon may occur when the light source is reflected from the upper surface of the light emitting stack EST or the upper surface of the pixel electrode AE.

For example, as the pixels PX0 of the display device 10 according to the comparative example are repeatedly throughout the display area DA, the first to third light emitting areas EA1, EA2, and EA3 are regularly arranged, so that external light reflected from each light emitting area EA may be separated into colors according to a wavelength or light of the same wavelength may constructively interfere to form a reflection diffraction pattern having a regular pattern.

As a result, as illustrated in FIG. 12, the halo pattern HLO0 of the display device 10 according to the comparative example may have a shape in which concentric circles of different colors extend outward from the center. For example, due to the external light reflection diffraction phenomenon, the colors of the light emitting areas EA1, EA2, and EA3 may be separated to generate a repetitive ring-shaped pattern.

In addition, as illustrated in FIG. 13, a phenomenon of color separation may occur in the diffraction pattern DFF0 of the display device 10 according to the comparative example. For example, the diffraction pattern DFF0 of the display device 10 according to the comparative example may be separated into a first color portion DFFR, a second color portion DFFG, and a third color portion DFFB.

In contrast, as illustrated in FIG. 14, a pixel PX1 of the display device 10 according to a first embodiment may include the concave portions CCV within the light emitting areas EA1, EA2, and EA3. A depth of the concave portion CCV included in the pixel PX1 of the display device 10 according to the first embodiment may be approximately 0.4 μm, and a width thereof may be approximately 3 μm to 6 μm. For example, the depth of the concave portion CCV in the pixel PX1 of the display device 10 according to the first embodiment may be kept constant at approximately 0.4 μm. The width of the concave portion CCV in the pixel PX1 of the display device 10 according to the first embodiment may have any value between approximately 3 μm and 6 μm, regardless of the type (kind) of the light emitting areas EA1, EA2, and EA3.

In this case, as illustrated in FIG. 15, the halo pattern HLO1 of the display device 10 according to the first embodiment may have the form of concentric circle or ring-shaped pattern that is vague and blurred. In addition, as illustrated in FIG. 16, a phenomenon of color separation in the diffraction pattern DFF1 of the display device 10 according to the first embodiment may be minimized. For example, the separation pattern such as the third color portion DFFB of the diffraction pattern DFF0 of the display device 10 according to the comparative example may also not occur, and the separation patterns that are clearly separated, such as the first color portion DFFR and the second color portion DFFG of the display device 10 according to the comparative example, may not occur. For example, the pixel PX1 of the display device 10 according to the first embodiment may minimize the external light reflection diffraction phenomenon by further including the concave portions CCV within the light emitting areas EA1, EA2, and EA3.

In some embodiments, as illustrated in FIG. 17, a pixel PX2 of the display device 10 according to a second embodiment may also include the concave portions CCV within the light emitting areas EA1, EA2, and EA3. A depth of the concave portion CCV included in the pixel PX2 of the display device 10 according to the second embodiment may be approximately 0.2 μm to 0.4 μm, and a width thereof may be approximately 3 μm to 6 μm. For example, the depth of the concave portion CCV in the pixel PX2 of the display device 10 according to the second embodiment may have any value between approximately 0.2 μm and 0.4 μm. The width of the concave portion CCV in the pixel PX2 of the display device 10 according to the second embodiment may have any value between approximately 3 μm and 6 μm, regardless of the type (kind) of the light emitting areas EA1, EA2, and EA3. The pixel PX2 of the display device 10 according to the second embodiment may have a more diverse distribution of the depth of the concave portion CCV than the pixel PX1 of the display device 10 according to the first embodiment.

In this case, as illustrated in FIG. 18, the halo pattern HLO2 of the display device 10 according to the second embodiment may have a more vague concentric circle or ring-shaped pattern than the halo pattern HLO1 of the display device 10 according to the first embodiment. In some embodiments, as illustrated in FIG. 19, the diffraction pattern DFF2 of the display device 10 according to the second embodiment may have a more blurry shape than the diffraction pattern DFF1 of the display device 10 according to the first embodiment. For example, the pixel PX2 of the display device 10 according to the second embodiment has a distribution of one or more suitable depths of the concave portion CCV, so that the degree and direction of diffusion of reflected light are diversified, thereby further minimizing the external light reflection diffraction phenomenon.

In some embodiments, as illustrated in FIG. 20, a pixel PX3 of the display device 10 according to a third embodiment may also include the concave portions CCV within the light emitting areas EA1, EA2, and EA3. A depth of the concave portion CCV included in the pixel PX3 of the display device 10 according to the third embodiment may be approximately 0.4 μm, and a width thereof may be approximately 2 μm to 6 μm. For example, the depth of the concave portion CCV in the pixel PX3 of the display device 10 according to the third embodiment may be kept constant at approximately 0.4 μm. The width of the concave portion CCV in the pixel PX3 of the display device 10 according to the third embodiment may vary depending on the type (kind) of the light emitting areas EA1, EA2, and EA3. For example, in the pixel PX3 of the display device 10 according to the third embodiment, the width of the concave portion CCV of the first light emitting area EA1 may have any value between approximately 3 μm and 6 μm, the width of the concave portion CCV of the second light emitting area EA2 may have any value between approximately 2.5 μm and 5 μm, and the width of the concave portion CCV of the third light emitting area EA3 may have any value between approximately 2.2 μm and 4.4 μm. The pixel PX3 of the display device 10 according to the third embodiment may have a more diverse distribution of the width of the concave portion CCV than the pixel PX1 of the display device 10 according to the first embodiment. For example, the pixel PX3 of the display device 10 according to the third embodiment may vary the range of the width of the concave portion CCV in consideration of the wavelength of light emitted from each of the light emitting areas EA1, EA2, and EA3.

In this case, as illustrated in FIG. 21, the halo pattern HLO3 of the display device 10 according to the third embodiment may have a more vague concentric circle or ring-shaped pattern than the halo pattern HLO1 of the display device 10 according to the first embodiment. In addition, as illustrated in FIG. 22, the diffraction pattern DFF3 of the display device 10 according to the third embodiment may have a more blurry shape than the diffraction pattern DFF1 of the display device 10 according to the first embodiment. For example, as the pixel PX3 of the display device 10 according to the third embodiment has a distribution of one or more suitable widths of the concave portion CCV depending on the type (kind) of the light emitting areas EA1, EA2, and EA3, the diffraction angles of reflected light are different, thereby further minimizing the external light reflection diffraction phenomenon.

In some embodiments, as illustrated in FIG. 23, a pixel PX4 of the display device 10 according to a fourth embodiment may also include the concave portions CCV within the light emitting areas EA1, EA2, and EA3. A depth of the concave portion CCV included in the pixel PX4 of the display device 10 according to the fourth embodiment may be approximately 0.2 μm to 0.4 μm, and a width thereof may be approximately 2 μm to 6 μm. For example, the depth of the concave portion CCV in the pixel PX4 of the display device 10 according to the fourth embodiment may have any value between approximately 0.2 μm and 0.4 μm. The width of the concave portion CCV in the pixel PX4 of the display device 10 according to the fourth embodiment may vary depending on the type (kind) of the light emitting areas EA1, EA2, and EA3. For example, in the pixel PX4 of the display device 10 according to the fourth embodiment, the width of the concave portion CCV of the first light emitting area EA1 may have any value between approximately 3 μm and 6 μm, the width of the concave portion CCV of the second light emitting area EA2 may have any value between approximately 2.5 μm and 5 μm, and the width of the concave portion CCV of the third light emitting area EA3 may have any value between approximately 2.2 μm and 4.4 μm. The pixel PX4 of the display device 10 according to the fourth embodiment may have a more diverse distribution of the width of the concave portion CCV than the pixel PX2 of the display device 10 according to the second embodiment. For example, the pixel PX4 of the display device 10 according to the fourth embodiment may vary the range of the width of the concave portion CCV in consideration of the wavelength of light emitted from each of the light emitting areas EA1, EA2, and EA3.

In this case, as illustrated in FIG. 24, the halo pattern HLO4 of the display device 10 according to the fourth embodiment may have a more vague concentric circle or ring-shaped pattern than the halo pattern HLO2 of the display device 10 according to the second embodiment. In addition, as illustrated in FIG. 25, the diffraction pattern DFF4 of the display device 10 according to the fourth embodiment may have a more blurry shape than the diffraction pattern DFF2 of the display device 10 according to the second embodiment. For example, as the pixel PX4 of the display device 10 according to the fourth embodiment has a distribution of one or more suitable widths of the concave portion CCV depending on the type (kind) of the light emitting areas EA1, EA2, and EA3, the diffraction angles of reflected light are different, thereby further minimizing the external light reflection diffraction phenomenon.

Terms such as “substantially,” “about,” and “approximately” are used as relative terms and not as terms of degree, and are intended to account for the inherent deviations in measured or calculated values that would be recognized by those of ordinary skill in the art. They may be inclusive of the stated value and an acceptable range of deviation as determined by one of ordinary skill in the art, considering the limitations and error associated with measurement of that quantity. For example, “about” may refer to one or more standard deviations, or +30%, 20%, 10%, 5% of the stated value.

Numerical ranges disclosed herein include and are intended to disclose all subsumed sub-ranges of the same numerical precision. For example, a range of “1.0 to 10.0” includes all subranges having a minimum value equal to or greater than 1.0 and a maximum value equal to or less than 10.0, such as, for example, 2.4 to 7.6. Applicant therefore reserves the right to amend this specification, including the claims, to expressly recite any sub-range subsumed within the ranges expressly recited herein.

The light-emitting device, the electronic apparatus, the electronic device, a device of manufacturing thereof, and/or any other relevant devices or components according to embodiments of the present disclosure described herein may be implemented utilizing any suitable hardware, firmware (e.g., an application-specific integrated circuit), software, or a combination of software, firmware, and hardware. For example, the one or more suitable components of the light-emitting device and the electronic apparatus and/or device may be formed on one integrated circuit (IC) chip or on separate IC chips. Further, the one or more suitable components of the light-emitting device and the electronic apparatus and/or device may be implemented on a flexible printed circuit film, a tape carrier package (TCP), a printed circuit board (PCB), or formed on one substrate. Further, the one or more suitable components of the light-emitting device and the electronic apparatus and/or device may be a process or thread, running on one or more processors, in one or more computing devices, executing computer program instructions and interacting with other system components for performing the one or more suitable functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, and/or the like. Also, a person of skill in the art should recognize that the functionality of one or more suitable computing devices may be combined or integrated into a single computing device, or the functionality of a particular computing device may be distributed across one or more other computing devices without departing from the scope of the embodiments of the present disclosure.

A person of ordinary skill in the art, in view of the present disclosure in its entirety, would appreciate that each suitable feature of the one or more suitable embodiments of the present disclosure may be combined or combined with each other, partially or entirely, and may be technically interlocked and operated in one or more suitable ways, and each embodiment may be implemented independently of each other or in conjunction with each other in any suitable manner unless otherwise stated or implied. However, the aspects and features of embodiments of the present disclosure are not limited to those described herein, and one or more suitable other aspects and features as would be understood by those having ordinary skill in the art may be included in the present disclosure.

In the context of the present application and unless otherwise defined, the terms “use,” “using,” and “used” may be considered synonymous with the terms “utilize,” “utilizing,” and “utilized,” respectively.

In concluding the detailed description, those skilled in the art will appreciate that many variations and modifications can be made to the preferred embodiments without substantially departing from the principles of the present disclosure. Therefore, the disclosed preferred embodiments of the present disclosure are used in a generic and descriptive sense only and not for purposes of limitation.

While one or more embodiments have been described with reference to the figures, it will be understood by those of ordinary skill in the art that suitable changes in form and details may be made therein without departing from the spirit and scope as defined by the following claims, and equivalents thereof.

What is claimed is:

1. A display device comprising:
a substrate;
a first pixel and a second pixel each including a plurality of light emitting elements, each plurality of light-emitting elements on the substrate and comprising a first electrode, a light emitting layer, and a second electrode;
an encapsulation film on each plurality of light emitting elements; and
a color filter layer on the encapsulation film,
wherein each first electrode of the first pixel and the second pixel comprises a plurality of concave portions on an upper surface of each first electrode and having a concave shape toward the substrate, and
a pattern of the plurality of concave portions in the first electrode of the first pixel is different from a pattern of the plurality of concave portions in the first electrode of the second pixel.

2. The display device of claim 1, wherein the plurality of concave portions in the first electrode of the first pixel are irregularly on the upper surface of the first electrode of the first pixel, and
the plurality of concave portions in the first electrode of the second pixel are irregularly on the upper surface of the first electrode of the second pixel.

3. The display device of claim 2, wherein in each of the first pixel and the second pixel,
the upper surface of the first electrode comprises a first portion and a second portion having a same area at different positions, and
a number of the plurality of concave portions on the first portion is different from a number of the plurality of concave portions on the second portion.

4. The display device of claim 2, wherein in each of the first pixel and the second pixel,
the upper surface of the first electrode comprises a first portion and a second portion each having a same area at different positions, and
an average size of the plurality of concave portions on the first portion is different from an average size of the plurality of concave portions on the second portion.

5. The display device of claim 1, wherein the plurality of light emitting elements in the first pixel are at a same position as the plurality of light emitting elements in the second pixel.

6. The display device of claim 1, wherein a portion of the plurality of concave portions at least partially overlap each other.

7. The display device of claim 1, wherein a portion of the plurality of concave portions have different sizes.

8. The display device of claim 7, wherein a maximum value of widths of the plurality of concave portions is at least twice of a minimum value.

9. The display device of claim 7, wherein a width of the plurality of concave portions is 2 micrometer (μm) to 6 μm.

10. The display device of claim 7, wherein a depth of the plurality of concave portions is 0.2 μm to 0.4 μm.

11. The display device of claim 1, wherein the plurality of light emitting elements include a first light emitting element configured to emit a first color, a second light emitting element configured to emit a second color, and a third light emitting element configured to emit a third color, and
a range of widths of the plurality of concave portions in the first electrode of the first light emitting element, a range of widths of the plurality of concave portions in the first electrode of the second light emitting element, and a range of widths of the plurality of concave portions in the first electrode of the third light emitting element are different from each other.

12. The display device of claim 11, wherein a wavelength of light of the first color is longer than a wavelength of light of the second color,
the wavelength of the light of the second color is longer than a wavelength of light of the third color,
a maximum value of the widths of the plurality of concave portions in the first electrode of the first light emitting element is greater than a maximum value of the widths of the plurality of concave portions in the first electrode of the second light emitting element, and
the maximum value of the widths of the plurality of concave portions in the first electrode of the second light emitting element is greater than a maximum value of the widths of the plurality of concave portions in the first electrode of the third light emitting element.

13. The display device of claim 11, wherein the range of widths of the plurality of concave portions in the first electrode of the first light emitting element is 3 μm to 6 μm,
the range of widths of the plurality of concave portions in the first electrode of the second light emitting element is 2.5 μm to 5 μm, and
the range of widths of the plurality of concave portions in the first electrode of the third light emitting element is 2.2 μm to 4.4 μm.

14. The display device of claim 1, wherein the encapsulation film comprises a first inorganic encapsulation film, an organic encapsulation film, and a second inorganic encapsulation film, and
the organic encapsulation film has a refractive index of 1.4 to 1.6.

15. The display device of claim 1, wherein upper surfaces of the light emitting layer and the second electrode each include concave portions conformally formed along a shape of the plurality of concave portions.

16. A display device comprising:
a substrate;
a first pixel and a second pixel each including first to third light emitting elements, each of the first to third light emitting elements being on the substrate and comprising a first electrode, a light emitting layer, and a second electrode, and each configured to emit first to third colors different from each other;
an encapsulation film on each of the first to third light emitting elements;
a color filter layer on the encapsulation film,
wherein an arrangement of the first to third light emitting elements in the first pixel is equal to an arrangement of the first to third light emitting elements in the second pixel,
the first electrodes of each of the first to third light emitting elements of each of the first pixel and the second pixel comprise a plurality of concave portions on an upper surface of the first electrodes and having a concave shape toward the substrate, and
a pattern of the plurality of concave portions in the first electrode of the first light emitting element of the first pixel is different from a pattern of the plurality of concave portions in the first electrode of the first light emitting element of the second pixel.

17. The display device of claim 16, wherein the plurality of concave portions in the first electrode of the first light emitting element of the first pixel are irregularly on the upper surface of the first electrode of the first light emitting element of the first pixel, and
the plurality of concave portions in the first electrode of the first light emitting element of the second pixel are irregularly on the upper surface of the first electrode of the first light emitting element of the second pixel.

18. The display device of claim 16, wherein a portion of the plurality of concave portions at least partially overlap each other.

19. The display device of claim 16, wherein in each of the first light emitting element of the first pixel and the second light emitting element of the second pixel,
the upper surface of the first electrode comprises a first portion and a second portion having a same area at different positions, and
an average size of the plurality of concave portions on the first portion is different from an average size of the plurality of concave portions on the second portion.

20. An electronic device including a display device, wherein the display device includes:
a substrate;
a first pixel and a second pixel each including a plurality of light emitting elements, each plurality of light-emitting elements on the substrate and comprising a first electrode, a light emitting layer, and a second electrode;
an encapsulation film on each plurality of light emitting elements; and
a color filter layer on the encapsulation film;
wherein each first electrode of the first pixel and the second pixel comprises a plurality of concave portions on an upper surface of each first electrode and having a concave shape toward the substrate, and
a pattern of the plurality of concave portions included in the first electrode of the first pixel is different from a pattern of the plurality of concave portions in the first electrode of the second pixel.
